(19) United States
(12) Patent Application Publication
(10) Pub. No.: US 2026/0013338 A1
(43) Pub. Date: Jan. 8, 2026

(54) DISPLAY PANEL

(71) Applicants: Hefei Visionox Technology Co., Ltd., Hefei (CN); KunShan Go-Visionox Opto-Electronics Co., Ltd., Suzhou (CN)

(72) Inventors: Yuan YAO, Hefei (CN); Chuanzhi XU, Hefei (CN); Zhichao ZHANG, Hefei (CN); Zhengkui DONG, Hefei (CN); Yingzi ZHAO, Hefei (CN)

(73) Assignees: Hefei Visionox Technology Co., Ltd., Hefei (CN); KunShan Go-Visionox Opto-Electronics Co., Ltd., Suzhou (CN)

(21) Appl. No.: 19/326,748

(22) Filed: Sep. 12, 2025

Related U.S. Application Data
(63) Continuation-in-part of application No. 18/938,314, filed on Nov. 6, 2024.
Application No. 18/938,314 is a continuation of application No. PCT/CN2024/099419, filed on Jun. 14, 2024.

(30) Foreign Application Priority Data
Jun. 16, 2023 (CN) 202310721853.3
Jun. 16, 2023 (CN) 202310730898.7
Jun. 27, 2023 (CN) 202310775927.1
Aug. 14, 2023 (CN) 202311029013.7

(51) Int. Cl. H10K 59/122; H10K 59/131; H10K 59/40; H10K 59/80

(52) U.S. Cl. CPC H10K 59/122; H10K 59/131; H10K 59/40; H10K 59/80515; H10K 59/80521; H10K 59/873

(57) ABSTRACT

Disclosed are a display panel. The display panel includes: a substrate; a pixel defining layer, located on the substrate and including a plurality of fourth openings; an isolation structure layer, provided on the pixel defining layer, where the isolation structure layer includes a light-transmitting portion and a plurality of isolation openings, and an orthographic projection of an isolation opening on the substrate at least partially overlaps with an orthographic projection of a fourth opening on the substrate; and a display function layer, including a light-emitting device provided corresponding to the isolation opening; where an orthographic projection of the light-transmitting portion on the substrate overlaps with an orthographic projection of the pixel defining layer on the substrate The display panel may be applied to the field of under-screen recognition.

### CROSS-REFERENCE TO RELATED APPLICATIONS

This application is a continuation-in-part of U.S. application Ser. No. 18/938,314, filed on Nov. 6, 2024, which is a continuation of International Application No. PCT/CN2024/099419, filed on Jun. 14, 2024. The International Application claims priority to Chinese Patent Application No. 202310730898.7, filed on Jun. 16, 2023, Chinese Patent Application No. 202310721853.3, filed on Jun. 16, 2023, Chinese Patent Application No. 202310775927.1, filed on Jun. 27, 2023, and Chinese Patent Application No. 202311029013.7, filed on Aug. 14, 2023. All of the aforementioned patent applications are hereby incorporated by reference in their entireties.

### FIELD

The present disclosure relates to the field of display technologies, and in particular, to a display panel.

### BACKGROUND

An Organic Light-Emitting Diode (OLED) is a kind of organic thin-film electroluminescent device. Due to advantages such as simple preparation process, low cost, low power consumption, high brightness, wide viewing angle, high contrast, and the ability to achieve flexible display, OLED attracted great attention and has been widely used in electronic display products.

However, currently, electronic display products are limited by design of their own structures, making it difficult to further reduce a pixel gap and apply them to the field of under-screen recognition.

### SUMMARY

The present disclosure provides a display panel. The display panel includes: a substrate; a pixel defining layer, located on the substrate and including a plurality of fourth openings; an isolation structure layer, provided on the pixel defining layer, where the isolation structure layer includes a light-transmitting portion and a plurality of isolation openings, and an orthographic projection of an isolation opening on the substrate at least partially overlaps with an orthographic projection of a fourth opening on the substrate; and a display function layer, including a light-emitting device provided corresponding to the isolation opening; where an orthographic projection of the light-transmitting portion on the substrate overlaps with an orthographic projection of the pixel defining layer on the substrate.

### BRIEF DESCRIPTION OF THE DRAWINGS

FIG. 1 is a planar view of a display panel according to an embodiment of the present disclosure.

FIG. 2 is an enlarged view of a region S1 of the display panel shown in FIG. 1.

FIG. 3 is a planar view of an isolation structure layer of the display panel shown in FIG. 2.

FIG. 4 is a cross-sectional view of the display panel in FIG. 2 along M1-N1.

FIG. 5 is a cross-sectional view of the display panel in FIG. 2 along M2-N2.

FIG. 6 is an enlarged view of a partial region of a first region of another display panel according to an embodiment of the present disclosure.

FIG. 7 is a planar view of an isolation structure layer of the display panel shown in FIG. 6.

FIG. 8 is an enlarged view of a partial region of a first region of still another display panel according to an embodiment of the present disclosure.

FIG. 9 is a planar view of an isolation structure layer of the display panel shown in FIG. 8.

FIG. 10 is an enlarged view of a partial region of a first region of yet still another display panel according to an embodiment of the present disclosure.

FIG. 11 is a planar view of an isolation structure layer of the display panel shown in FIG. 10.

FIG. 12 is an enlarged view of a partial region of a first region of yet still another display panel according to an embodiment of the present disclosure.

FIG. 13 is a planar view of an isolation structure layer of the display panel shown in FIG. 12.

FIG. 14 is an enlarged view of a partial region of a first region of still another display panel according to an embodiment of the present disclosure.

FIG. 15 is an enlarged view of a partial region of a first region of yet still another display panel according to an embodiment of the present disclosure.

FIG. 16 is a cross-sectional view of a partial region of another display panel according to an embodiment of the present disclosure.

FIG. 17 is an enlarged view of a partial region of a first region of yet still another display panel according to an embodiment of the present disclosure.

FIG. 18 is a planar view of a display panel according to an embodiment of the present disclosure.

FIG. 19 is a planar view of a display panel according to another embodiment of the present disclosure.

FIG. 20 is a planar view of a display panel according to still another embodiment of the present disclosure.

FIG. 21 is a planar view of a display panel according to yet still another embodiment of the present disclosure.

FIG. 22 is a planar view of a display panel according to yet still another embodiment of the present disclosure.

FIG. 23 is a planar view of a display panel according to yet still another embodiment of the present disclosure.

FIG. 24 is a cross-sectional view of a partial region of a display panel according to still another embodiment of the present disclosure.

FIG. 25 is a cross-sectional view of a partial region of a display panel according to yet still another embodiment of the present disclosure.

FIG. 26 is a planar view of a display panel according to yet still another embodiment of the present disclosure.

FIG. 27 is a cross-sectional view of a partial region of a display panel according to yet still another embodiment of the present disclosure.

FIG. 28 is a cross-sectional view of a partial region of a display panel according to yet still another embodiment of the present disclosure.

FIG. 29 is a cross-sectional view of a partial region of a display panel according to yet still another embodiment of the present disclosure.

FIG. 30 is a cross-sectional view of a partial region of a display panel according to yet still another embodiment of the present disclosure.

FIG. 31 is a cross-sectional view of a partial region of a display panel according to yet still another embodiment of the present disclosure.

FIG. 32 is a cross-sectional view of a partial region of a display panel according to yet still another embodiment of the present disclosure.

FIG. 33 is a cross-sectional view of a partial region of a display panel according to yet still another embodiment of the present disclosure.

FIG. 34 is a cross-sectional view of a partial region of a display panel according to yet still another embodiment of the present disclosure.

FIG. 35 is a cross-sectional view of the display panel shown in FIG. 23 along M1-N1.

FIG. 36 is a planar view of a touch electrode block of a touch electrode layer with a grid pattern of the display panel shown in FIG. 23.

FIG. 37 is a planar view of a touch electrode layer of a display panel according to another embodiment of the present disclosure, where the region S2 in FIG. 37 corresponds to the region S1 in FIG. 1.

FIG. 38 is a cross-sectional view of the display panel shown in FIG. 37 along M2-N2.

FIG. 39 is a planar view of a touch electrode layer of another display panel according to another embodiment of the present disclosure.

FIG. 40 is a cross-sectional view of the display panel shown in FIG. 39 along M3-N3.

FIG. 41 is an enlarged view of the region S1 of a display panel under another design shown in FIG. 1.

FIG. 42 is a planar view of a touch electrode block of a touch electrode layer with a grid pattern of the display panel shown in FIG. 41.

FIG. 43 is a cross-sectional view of a partial region of a display panel according to yet still another embodiment of the present disclosure.

FIG. 44 is a flowchart of a preparation method for the display panel shown in FIG. 43.

FIG. 45 is a cross-sectional view of a display device according to an embodiment of the present disclosure.

FIGS. 46 to 49 are process diagrams of a preparation method for a display panel according to an embodiment of the present disclosure.

FIGS. 50 to 53 are process diagrams of a preparation method for a display panel according to another embodiment of the present disclosure.

FIG. 54 is a cross-sectional view of a partial region of a display panel according to yet still another embodiment of the present disclosure.

FIG. 55 is a cross-sectional view of a partial region of a display panel according to yet still another embodiment of the present disclosure.

FIG. 56 is a cross-sectional view of a partial region of a display panel according to yet still another embodiment of the present disclosure.

### DETAILED DESCRIPTION OF THE EMBODIMENTS

A clear and complete description of the embodiments of the present disclosure will be provided with reference to accompanying drawings corresponding to the embodiments of the specification. Obviously, the embodiments described are only a part of embodiments of the specification, and not all embodiments.

As for a display product, some functional film layers in a light-emitting device may be prepared through evaporation. However, there are multiple types of the functional film layers in each light-emitting device, and materials of some functional film layers (such as a light-emitting layer) are different in light-emitting devices emitting light of different colors. Therefore, when these functional film layers are prepared through evaporation with a mask (such as a fine mask), alignment process needs to be performed for multiple times. To ensure alignment accuracy, sufficient space needs to be reserved between different light-emitting devices, thereby limiting arrangement density of the light-emitting devices (which may be referred to as sub-pixels). Thus, it is difficult to increase pixels per inch (PPI) of a display panel.

In the present disclosure, an isolation structure layer is provided at a gap between light-emitting devices to separate functional film layers of adjacent light-emitting devices. Thus, in the evaporation process of the functional film layers, it is only necessary to perform a full-surface evaporation on the display panel, without the need to use a mask to separately prepare each functional film layer. There is no need to consider the alignment accuracy during evaporation process, so that the gap between the light-emitting devices may be designed to be smaller in size to increase PPI.

However, the isolation structure layer may stop light from transmitting through the gap between the light-emitting devices, thereby affecting light transmission. Thus, it is difficult to apply the isolation structure layer to scenes such as under-screen fingerprint recognition and under-screen camera.

Embodiments of the present disclosure provide a display panel and a display device to at least solve the problem mentioned above. The display panel includes: a substrate; an isolation structure layer provided on the substrate, where the isolation structure layer includes a light-transmitting portion 30 and a plurality of isolation openings; a display function layer including a light-emitting device located within one of the plurality of isolation openings; and a touch structure located on a side, away from the substrate, of the isolation structure layer.

In this design, with application of the isolation structure layer, there is no need to use a mask during the preparation process of the light-emitting device, so that it is not necessary to consider the alignment accuracy during the preparation process, thereby reducing a size of a gap between the light-emitting devices and improving PPI of the display panel. In addition, by providing the light-transmitting portion in the isolation structure layer, an area of the display panel with the light-transmitting portion may allow light to transmit, so that off-screen recognition functions, such as fingerprint recognition and off-screen camera, may be realized.

A detailed explanation of structures of a display panel and a display device according to at least one embodiment of the present disclosure will be provided below with reference of the accompanying drawings. In addition, in these accompanying drawings, a space rectangular coordinate system is established based on the substrate of the display panel to visually present positional relationships of various components of the display panel. In the space rectangular coordinate system, X and Y axes are parallel to a surface of the substrate, and Z axis is perpendicular to the surface of the substrate.

As shown in FIG. 1, a flat region of a display panel 10 may be divided into a first region 13, a second region 11, and a border region 12 surrounding the second region 11. Sub-pixels such as R, G, and B pixels (the light-emitting devices 200 as entities) are arranged in the first region 13 and the second region 11. The second region 11 surrounds at least part of the first region 13, and the first region 13 is configured to have a certain light transmittance rate for off-screen recognition. In some embodiments of the present disclosure, part of wiring in the border region 12 may be arranged in the second region 11, so that the border region 12 may be designed as a single-sided border.

In some embodiments of the present disclosure, as shown in FIG. 1, in the display panel 10, only the first region 13 is configured to be transparent for under-screen recognition, that is, light transmittance rate of the second region 11 is lower than light transmittance rate of the first region 13, or the second region 11 is configured to be opaque.

In other embodiments of the present disclosure, the first region 13 may be design as an entire display region of the display panel, that is, there is no second region 11 mentioned above. Thus, the display panel may be used for full-screen recognition, such as full-screen fingerprint recognition. In one embodiment, part of the display panel may be used for off-screen camera, and the other part may be used for off-screen fingerprint recognition.

As shown in FIG. 1, the first region 13 of the display panel 10 may be arranged in any region of the display panel. For example, the first region 13 may be arranged at the middle of the display panel, and may also be arranged in the border region 12 of the display panel. Therein, the border region 12 includes edges and/or corners of the display panel.

In some embodiments of the present disclosure, light transmittance rate of the first region 13 of the display panel under test light is higher than 0.6%. Light transmittance rate of the first region 13 of the display panel under visible light is higher than 0.6%, so that the display panel may be configured with functions such as a photosensitive function. In one embodiment, light transmittance rate of the first region 13 of the display panel under light of 550 nm wavelength is higher than 0.6%, so that the display panel may be configured with functions such as the photosensitive function. In one embodiment, the light transmittance rate of the first region 13 of the display panel under visible light is higher than 0.9%; or the light transmittance rate of the first region 13 of the display panel under light of 550 nm wavelength is higher than 0.9%.

In some embodiments of the present disclosure, the display panel may further include a photosensor provided on the substrate. Furthermore, an orthographic projection of the photosensor on the substrate at least partially overlaps with an orthographic projection of the first region 13 on the substrate. The partial overlapping does not include complete overlapping.

The light transmittance rate of the first region 13 under test light being higher than 0.6% refers to that a detected light transmittance rate is higher than 0.6% when the test light transmits through the first region 13 of the display panel. All film structures of the display panel are influence factors of the light transmittance rate of the display panel.

Taking display panels shown in FIGS. 1 to 5 as examples, a detailed explanation of a specific structure of a display panel under a design provided by the present disclosure will be provided in the following.

A physical structure of a display panel 10 may include a substrate 100, and a display function layer 24 and an isolation structure layer located on the substrate 100. The isolation structure layer includes an isolation structure 300. The display function layer 24 includes a plurality of light-emitting devices 200, and the light-emitting device 200 includes a light-emitting unit 220. A plurality of isolation openings 301 are defined by the isolation structure 300, and each of the plurality of isolation openings 301 is provided with at least one light-emitting device 200.

In at least one embodiment of the present disclosure, the display function layer 24 is located in the first region 13 and the second region 11. Adjacent light-emitting units 220 are isolated by the isolation structure 300. Part of the isolation structure 300 that is located in the first region 13 is provided with at least one first light-transmitting opening 302 to allow a region of the display panel with the first light-transmitting opening 302 to transmit light for under-screen recognition. In this embodiment, the first light-transmitting opening 302 is the light-transmitting portion 30 of the isolation structure 300.

In at least one embodiment of the present disclosure, the light-emitting devices 200 may be classified to include a first light-emitting device R (emitting red light R), a second light-emitting device G (emitting green light G), and a third light-emitting device B (emitting blue light B). Wavelengths of the light emitted from the first light-emitting device R, the second light-emitting device G, and the third light-emitting device B decreases sequentially.

In the embodiment of the present disclosure, a plurality of first light-transmitting openings 302 may be dispersedly arranged at gaps between the light-emitting devices based on shapes and distribution of the light-emitting devices. In one embodiment, the first light-transmitting opening 302 may also be set as one to have a larger size, thereby increasing the light transmittance rate of the first region 13.

In the following, two designs of layout of the first light-transmitting opening 302 mentioned above will be described in detail through different embodiments, as well as structures of display panels corresponding to the two designs.

In some embodiments of the present disclosure, as shown in FIGS. 1 to 5, a plurality of first light-transmitting openings 302 are provided in the display panel. In the first region 13, the first light-emitting device R is disposed adjacent to the first light-transmitting opening 302. As a wavelength of light emitted from the first light-emitting device R is the longest, luminous efficiency of the first light-emitting device R is relatively higher. In practical process, the first light-transmitting opening 302 is ensured to be arranged around the first light-emitting device R In one embodiment, so that an adverse effect (area reduction) of the design of the first light-transmitting opening 302 on the second light-emitting device G and/or the third light-emitting device B may be reduced or avoided, thereby maintaining good display performance of the display device.

In some embodiments of the present disclosure, a ratio of an area of an orthographic projection of the first light-transmitting opening 302 on the substrate 100 to an area of an orthographic projection of the first region 13 on the substrate is greater than or equal to 1%. Furthermore, the ratio of the area of the orthographic projection of the first light-transmitting opening 302 on the substrate 100 to the area of the orthographic projection of the first region 13 on the substrate is greater than or equal to 6%. In one embodiment, the ratio of the area of the orthographic projection of the first light-transmitting opening 302 on the substrate 100 to the area of the orthographic projection of the first region 13 on the substrate is greater than or equal to 10%. In one embodiment, the ratio of the area of the orthographic projection of the first light-transmitting opening 302 on the substrate 100 to the area of the orthographic projection of the first region 13 on the substrate is greater than or equal to 30%. In one embodiment, the ratio of the area of the orthographic projection of the first light-transmitting opening 302 on the substrate 100 to the area of the orthographic projection of the first region 13 on the substrate is greater than or equal to 50%.

In other embodiments of the present disclosure, a ratio of the area of the orthographic projection of the first light-transmitting opening 302 on the substrate 100 to an area of an orthographic projection of the isolation structure 300 on the substrate 100 ranges from 1.50% to 9.50%, such as 1.5%, 2%, 3%, 4%, 5% or 5.5%. Further, the ratio of the area of the orthographic projection of the first light-transmitting opening 302 on the substrate 100 to the area of the orthographic projection of the first region 13 on the substrate 100 ranged from 6% to 10%, such as 6.5%, 7%, 8% or 9%. In one embodiment, the ratio of the area of the orthographic projection of the first light-transmitting opening 302 on the substrate 100 to the area of the orthographic projection of the first region 13 on the substrate 100 ranged from 10% to 30%, such as 11%, 12%, 13%, 18%, 20%, 21%, 23%, 25%, 28% or 29%. In one embodiment, the ratio of the area of the orthographic projection of the first light-transmitting opening 302 on the substrate 100 to the area of the orthographic projection of the first region 13 on the substrate 100 ranges from 30% to 50%, such as 35%, 40%, 42% or 45%.

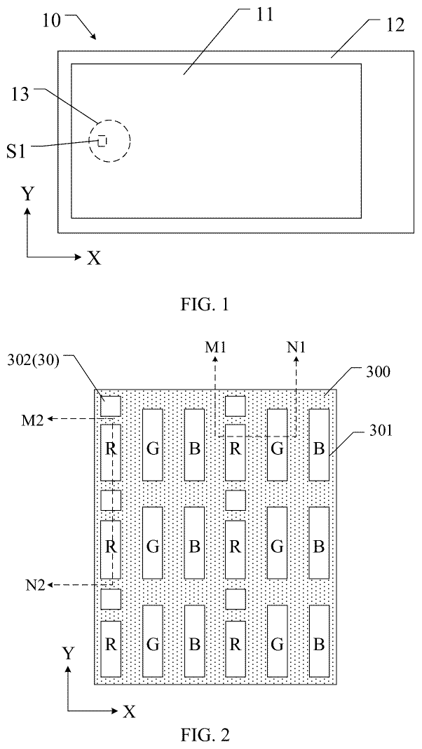

In some embodiments of the present disclosure, as shown in FIG. 2 and FIG. 3, along a length direction of the first light-emitting device R, the first light-emitting devices R and the first light-transmitting openings 302 corresponding to the first light-emitting devices R are arranged alternately in sequence. In this arrangement, there is no need to narrow a width of the first light-emitting device R for arranging the first light-transmitting opening 302, thereby reducing difficulty in arranging the first light-transmitting opening 302.

For example, space for arranging the first light-transmitting opening 302 may be reserved by reducing a size of the first light-emitting device R in the first region 13. That is, a length of the first light-emitting device R located in the first region 13 is less than a length of the first light-emitting device R located in the second region 11.

When the first light-transmitting opening 302 is disposed on one side of the light-emitting device, the size (such as length) of the light-emitting device will be affected. Therefore, the first light-transmitting opening 302 may be disposed adjacent to at least one of the first light-emitting device, the second light-emitting device, and the third light-emitting device. In the following, different choices mentioned above will be described through different embodiments.

In some embodiments of the present disclosure, as shown in FIGS. 1 to 5, in the first region 13, each of the first light-transmitting openings 302 is configured to be adjacent to a corresponding first light-emitting device R, that is, luminous efficiency of the second light-emitting device G and the third light-emitting device B will not be affected by arrangement of the first light-transmitting opening 302. For example, in the first region 13, a length of the second light-emitting device G is equal to a length of the third light-emitting device B, and the length of the second light-emitting device G is greater than a length of the first light-emitting device R, that is, in the first region 13, only the length of the first light-emitting device R need to be shortened for arrangement of the first light-transmitting opening 302.

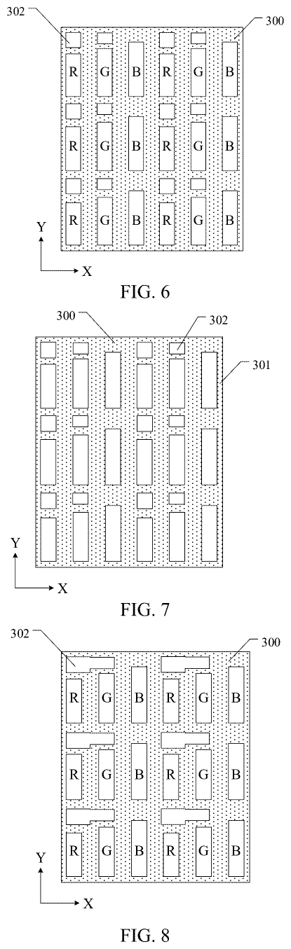

In other embodiments of the present disclosure, as shown in FIG. 6 and FIG. 7, in the first region, each of the first light-transmitting openings 302 is adjacent to the first light-emitting device R or the second light-emitting device G, that is, luminous efficiency of the third light-emitting device B will not be affected by arrangement of the first light-transmitting opening 302.

For example, as shown in FIG. 6 and FIG. 7, along a length direction of the first light-emitting device R, the first light-emitting devices R and the first light-transmitting openings 302 adjacent to the first light-emitting devices R are arranged alternately in sequence. Along a length direction of the second light-emitting device G, the second light-emitting devices G and the first light-transmitting openings 302 adjacent to the second light-emitting devices G are arranged alternately in sequence. For example, in the first region 13, the length of the third light-emitting device B is greater than the lengths of the first light-emitting device R and the second light-emitting device G, that is, in the first region 13, the lengths of the first light-emitting device R and the second light-emitting device G need to be shortened for arrangement of the first light-transmitting opening 302.

For example, in some embodiments, an area of the first light-transmitting opening 302 corresponding to the second light-emitting device G is equal to an area of the first light-transmitting opening 302 corresponding to the first light-emitting device R.

For example, in some other embodiments, as shown in FIG. 6 and FIG. 7, the area of the first light-transmitting opening 302 corresponding to the second light-emitting device G is less than the area of the first light-transmitting opening 302 corresponding to the first light-emitting device R. Thus, impact on luminous efficiency of the second light-emitting device G caused by arrangement of the first light-transmitting opening 302 may be reduced.

For example, as shown in FIG. 6 and FIG. 7, along Y axis direction (the length direction of the light-emitting device), the length of the first light-transmitting opening 302 corresponding to the second light-emitting device G is less than the length of the first light-transmitting opening 302 corresponding to the first light-emitting device R.

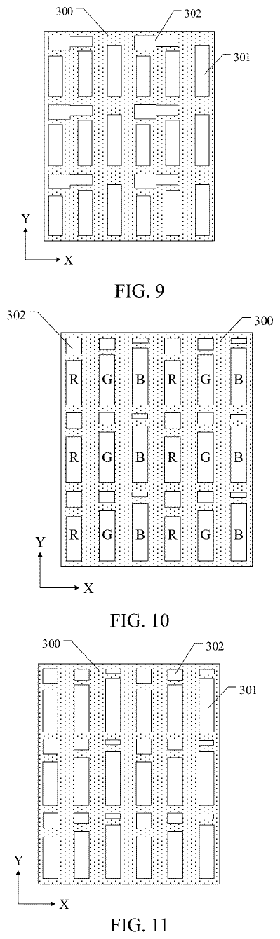

For example, as shown in FIG. 8 and FIG. 9, adjacent two first light-transmitting openings 302 respectively corresponding to the first light-emitting device R and the second light-emitting device G are communicated, thereby increasing a total area of the first light-transmitting openings 302 and increasing the light transmittance rate of the first region. Thus, in a case where the lengths of the first light-transmitting openings 302 respectively corresponding to the first light-emitting device R and the second light-emitting device G are different, a shape of an opening formed by two communicated first light-transmitting openings 302 respectively corresponding to the first light-emitting device R and the second light-emitting device G presents as a stepped shape (FIG. 8 shows a second-order shape).

As for the first light-transmitting opening 302 shown in FIGS. 6 to 9, space for arranging the first light-transmitting opening 302 may be reserved by reducing sizes of the first light-emitting device R and the second light-emitting device G in the first region, that is, the length of the second light-emitting device G located in the first region 13 is less than a length of the second light-emitting device G located in the second region 11.

In other embodiments of the present disclosure, as shown in FIG. 10 to FIG. 11, in the first region, each of the first light-transmitting openings 302 is adjacent to the first light-emitting device R, the second light-emitting device G, or the third light-emitting device B.

For example, as shown in FIG. 10 and FIG. 11, along a length direction of the second light-emitting device G, the second light-emitting devices G and the first light-transmitting openings 302 corresponding to the second light-emitting devices G are arranged alternately
in sequence, and/or along a length direction of the third light-emitting device B, the third light-emitting devices B and the first light-transmitting openings 302 corresponding to the third light-emitting devices B are arranged alternately in sequence.

For example, furthermore, an area of the first light-transmitting opening 302 corresponding to the second light-emitting device G is less than an area of the first light-transmitting opening 302 corresponding to the first light-emitting device R, and an area of the first light-transmitting opening 302 corresponding to the third light-emitting device B is less than the area of the first light-transmitting opening 302 corresponding to the second light-emitting device G, so that the length of the second light-emitting device G is greater than the length of the first light-emitting device R and less than the length of the third light-emitting device B. For example, as shown in FIG. 10 and FIG. 11, along Y-axis direction (length direction of the light-emitting device), a length of the first light-transmitting opening 302 corresponding to the second light-emitting device G is less than a length of the first light-transmitting opening 302 corresponding to the first light-emitting device R, and greater than a length of the first light-transmitting opening 302 corresponding to the third light-emitting device B. Thus, in the first region 13, the lengths of the first light-emitting device R, the second light-emitting device G, and the third light-emitting device B increase sequentially, thereby avoiding occurrence of color deviation in the display device due to low luminous efficiency of some light-emitting devices, such as the third light-emitting device B.

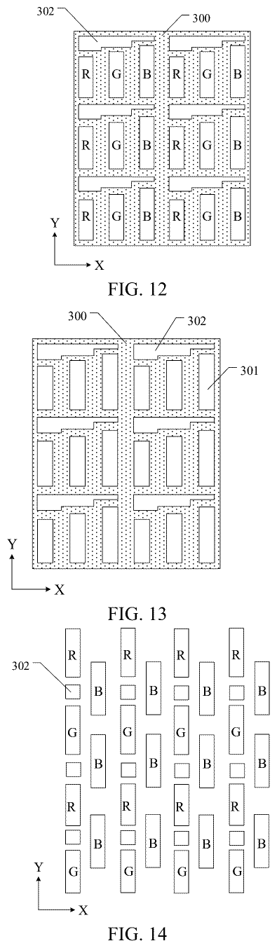

For example, as shown in FIG. 12 and FIG. 13, the first light-transmitting openings 302 respectively corresponding to the first light-emitting device R, the second light-emitting device G, and the third light-emitting device B are communicated, thereby further increasing a total area of the first light-transmitting openings 302 and increasing the light transmittance rate of the first region. Thus, a shape of an opening formed by three communicated first light-transmitting openings 302 respectively corresponding to the first light-emitting device R and the second light-emitting device G and the third light-emitting device B presents as a stepped shape (FIG. 12 shows a third-order shape).

As for the first light-transmitting opening 302 shown in FIGS. 10 to 13, space for arranging the first light-transmitting opening 302 may be reserved by reducing sizes of the first light-emitting device R, the second light-emitting device G, and the third light-emitting device B in the first region 13, that is, the length of the second light-emitting device G located in the first region is less than a length of the second light-emitting device G located in the second region, and the length of the third light-emitting device B located in the first region 13 is less than a length of the third light-emitting device B located in the second region.

In some embodiments of the present disclosure, in a case where a plurality of first light-transmitting openings are provided in the display panel, the arrangement of the first light-transmitting openings may be adjusted based on arrangement of the light-emitting devices. In the following, a description of the arrangement mentioned above will be provided through several specific examples.

In some embodiments of the present disclosure, referring back to FIG. 2, FIGS. 7 to 13, the first light-emitting device R, the second light-emitting device G, and the third light-emitting device B are arranged in plural rows and columns, with a row direction being X-axis direction and a column direction being Y-axis direction. The first light-emitting device R, the second light-emitting device G, and the third light-emitting device B are located in different columns, that is, the light-emitting devices of the same column have emitted light of a same color. The first light-emitting devices R, the second light-emitting devices G, and the third light-emitting devices B are arranged in row alternately in sequence. For example, in each row, the first light-emitting device R, the second light-emitting device G, and the third light-emitting device B adjacent to each other form a pixel (which may be referred to as a pixel unit or a pixel group, and each light-emitting device may be referred to as a sub-pixel). For example, furthermore, length directions of the first light-emitting device R, the second light-emitting device G, and the third light-emitting device B are the same as the column direction.

In other embodiments of the present disclosure, as shown in FIG. 14, the first light-emitting device R, the second light-emitting device G, and the third light-emitting device B are arranged in plural rows and columns. Some columns are arranged with the first light-emitting device R and the second light-emitting device G, while the other columns are arranged with the third light-emitting device B. In the columns with the first light-emitting device R, the first light-emitting devices R and the second light-emitting devices G are arranged alternately along the column direction. The columns with the first light-emitting device R and the second light-emitting device G and the columns with the third light-emitting device B are arranged alternately along the row direction. For example, the first light-emitting device R, the second light-emitting device G, and the third light-emitting device B adjacent to each other form a pixel (which may be referred to as a pixel unit or a pixel group, and each light-emitting device may be referred to as a sub-pixel). This design may increase a design area of the third light-emitting device B (such as by increasing the length), thereby ensuring luminous efficiency of the third light-emitting device B. For example, furthermore, the length direction of the first light-emitting device R, the second light-emitting device G, and the third light-emitting device B is the same as the column direction. In this design, a first light-transmitting opening 302 may be arranged between adjacent first light-emitting device R and second light-emitting device G in the same column. As the design shown in FIG. 14, a quantity of the third light-emitting device B in each column is about half of a quantity of light-emitting devices in an adjacent column. Therefore, in some designs, luminous efficiency of the third light-emitting device B may be improved by increasing a design area of the third light-emitting device B (such as by increasing the length). In one embodiment, in other designs, the design area of the third light-emitting device B may be kept constant, so that there is a large gap between adjacent third light-emitting devices B. Thus, the first light-transmitting opening 302 may also be arranged between adjacent third light-emitting devices B.

As shown in FIGS. 2 to 14, in the case where a plurality of first light-transmitting openings 302 are provided in the display panel, an isolation opening 301 may be designed to be in a one-to-one correspondence with the light-emitting device 200, so that only one light-emitting device 200 is disposed in each isolation opening 301.

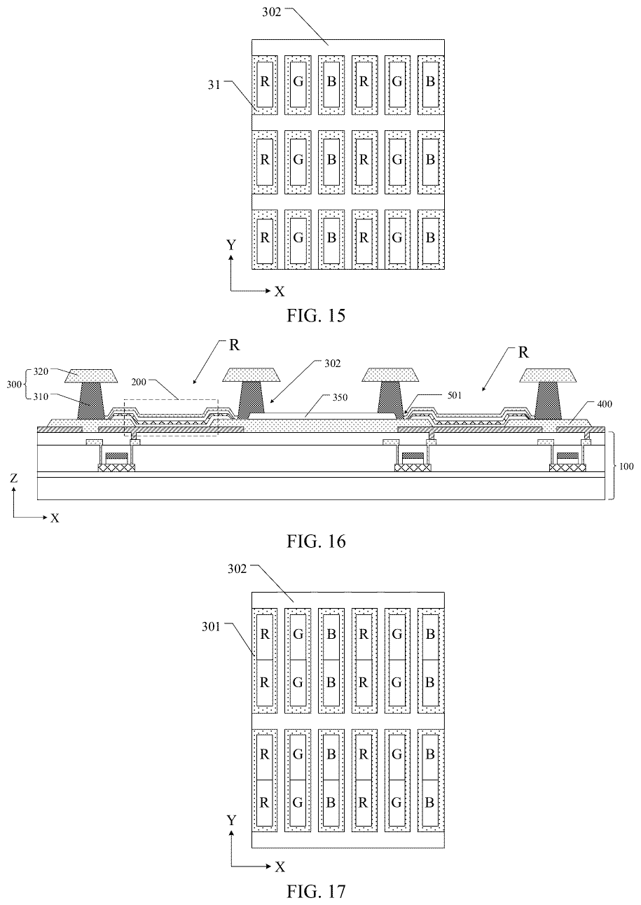

In a case where the first light-transmitting opening 302 is configured to be presented in a grid shape, each first light-transmitting opening 302 (corresponding to the isolation opening 301) may be provided with a light-emitting device 200 (as shown in FIG. 15), or a plurality of light-emitting devices 200.

For example, as shown in FIG. 17, at least two light-emitting devices 200 are provided in each isolation opening 301, and colors of light emitted from light-emitting devices 200 located in the same isolation opening 301 are the same. A difference in driving voltage between light-emitting devices 200 with the same color of the emitted light is small. Even if the light-emitting devices 200 are disposed in the same isolation opening 301, a degree of current crosstalk will be relatively low. Thus, by arranging light-emitting devices 200 with a same color of emitted light in one isolation opening 301, a distance between adjacent light-emitting devices 200 located in different isolation openings 301 may be increased without reducing a design area and pixels per inch (PPI) of the light-emitting devices 200, thereby reducing preparation difficulty of the first light-transmitting opening 302 in the isolation structure 300 to facilitate designing the first light-transmitting opening 302 to be a grid shape.

The isolation structure 300 is further described in patents including No. PCT/CN2023/134518, No. 202310759370.2, No. 202310740412.8, No. 202310707209.0, No. 202311346196.5, No. 202311499823.9, No. 202310731471.9, and No. 202311091555.7 for reference.

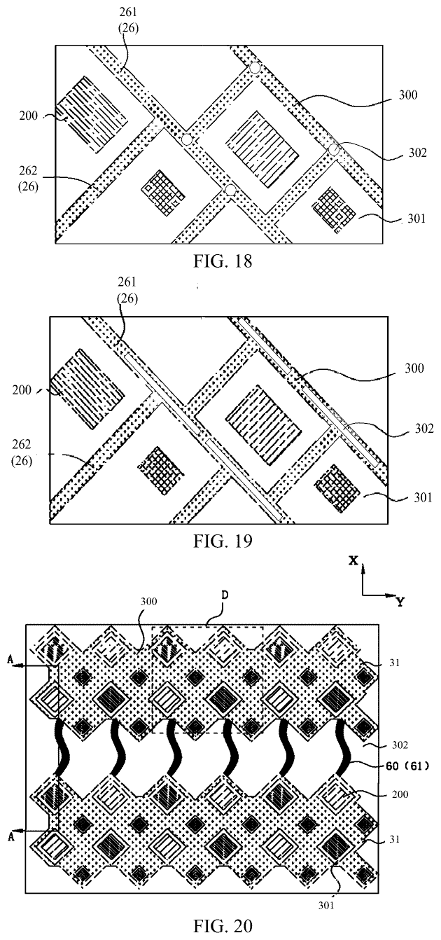

Taking display panels shown in FIGS. 18 to 22 as an example, a specific structure of a display panel under another design provided by the present disclosure will be described in detail in the following.

In some embodiments of the present disclosure, as shown in FIG. 18, the isolation structure 300 includes a plurality of isolation segments 26 extending in two directions which intersect with each other. A first light-transmitting opening 302 is configured to extend through the isolation segments 26 along a thickness direction of the substrate 100.

The isolation structure 300 includes a plurality of isolation segments 26, and at least part of the isolation segments 26 have different extension directions. Each isolation segment 26 may be a straight segment structure, or a curving segment structure 61. In one embodiment, part of the isolation segments 26 may be straight segment structures, and the other part of the isolation segments 26 may be curving segment structures 61. When the isolation segment 26 is the curved structure or other non-linear structure, an extension direction of the isolation segment 26 refers to a direction of a line connecting a head end and a tail end of the isolation segment 26.

In other embodiments of the present disclosure, as shown in FIG. 18, the isolation structure 300 includes a plurality of isolation segments 26 intersecting with each other, and the plurality of isolation segments 26 include a first isolation portion 261 and a second isolation portion 262 intersected with each other. The first light-transmitting opening 302 is arranged at an intersection of the first isolation portion 261 and the second isolation portion 262. In other embodiments of the present disclosure, as shown in FIG. 19, the first light-transmitting opening 302 is arranged in the first isolation portion 261 and extends along a length direction of the first isolation portion 261.

By disposing the first light-transmitting opening 302 at the intersection of the first isolation portion 261 and the second isolation portion 262, a distance between a center of the first light-transmitting opening 302 and a center of an adjacent isolation opening 301 may be increased, thereby reducing influence of the first light-transmitting opening 302 on the isolation opening 301. Of course, in some other embodiments, the first light-transmitting opening 302 may also be arranged in the second isolation portion 262, which is not limited in the present disclosure.

In one embodiment, a shape of an orthographic projection of the first light-transmitting opening 302 on the substrate 100 may be circular, polygonal, rectangular, or irregular, which is not limited in the present disclosure.

In some embodiments, as shown in FIG. 20, the isolation structure 300 includes a plurality of isolation units 31, and an isolation opening 301 is defined by the isolation unit 31. At least part of isolation units 31 adjacent to each other are spaced apart to form the first light-transmitting opening 302.

The isolation structure 300 includes the plurality of isolation units 31 disposed with intervals. Structures of different isolation units 31 may be the same or different. The isolation opening 301 is defined by the isolation unit 31. Therein, the isolation unit 31 may be provided with one isolation opening 301, or the isolation unit 31 may also be provided with a plurality of isolation openings 301 at the same time, which is not limited in the present disclosure. In this embodiment of the present disclosure, the isolation structure 300 is configured to include a plurality of isolation units 31 spaced apart from each other to form the first light-transmitting opening 302 located between adjacent isolation units 31. This helps to further increase a size of the first light-transmitting opening 302 in the display panel, thereby improving an overall light transmittance rate of the display panel and improving practicality.

In other embodiments of the present disclosure, as shown in FIG. 15 and FIG. 16, a shape of an orthographic projection of the first light-transmitting opening 302 on the substrate 100 is a grid. Thus, a total area of the first light-transmitting opening 302 of the isolation structure 300 in the first region increases, thereby improving the light transmittance rate of the first region.

As shown in FIG. 15, in the first region, the isolation structure 300 may be separated into a plurality of isolation units 31 spaced apart from each other by the grid-like first light-transmitting openings 302, and the isolation opening is defined by the isolation unit 31.

In the embodiments of the present disclosure, the isolation units 31 may be connected by providing a transparent electrode. For example, as shown in FIG. 16, the display panel may further include a transparent conductive layer 350. The transparent conductive layer 350 is located between the isolation structure 300 and the substrate 100 and connected to the isolation structure 300. The conductive layer 350 is provided with a third opening 501, and the third opening 501 corresponds to the isolation opening 301. An orthographic projection of the isolation opening 301 on the substrate 100 is located within an orthographic projection of a corresponding third opening 501 on the substrate 100. An orthographic projection of the first light-transmitting opening 302 on the substrate 100 is located within an orthographic projection of the conductive layer on the substrate 100. Thus, the isolation units 31 are connected through the transparent conductive layer 350, so that first electrodes 210 may be electrically connected to each other through the conductive layer 350 and the isolation structure 300 to form a common electrode.

In other embodiments of the present disclosure, as shown in FIG. 54, the display panel 10 may further include a light-emitting unit 220 and a second electrode 230 sequentially stacked in layers, which are located on a side, close to the isolation structure 300, of the substrate 100 and disposed in the first light-transmitting opening 302. In some embodiments, the display panel 10 may further include a thin film made of organic material, located on a side, away from the display function layer 24, of the second electrode 230. In one embodiment, the display panel 10 may further include a plurality of thin films located on the side, away from the display function layer 24, of the second electrode 230, and the plurality of thin films have different refractive indices.

Meanwhile, according to embodiments of the present disclosure, the display panel may be stretched. Specifically, as the isolation units 31 are spaced apart from each other, when the display panel needs to be stretched, a relative distance between different isolation units 31 may be increased under external forces and other factors. As the light-emitting device 200 are only provided in a correspond isolation opening 301 of the isolation unit 31, there is no light-emitting device 200 between adjacent isolation units 31. Therefore, when a position of the isolation unit 31 change, the light-emitting device 200 may move with the isolation unit 31, and a distance between different light-emitting devices 200 located at different isolation units 31 is increased, thereby achieving adjustment of relative position between different light-emitting devices 200 and meeting a stretching requirement.

In some embodiments, the isolation unit 31 is provided with a plurality of isolation openings 301. That is, a plurality of light-emitting devices 200 may be disposed in a same isolation unit 31. In one embodiment, at least part of the light-emitting devices 200 of different colors may disposed within the plurality of isolation openings 301 of the same isolation unit 31.

In some embodiments, at least part of the light-emitting devices 200 are arranged side by side in a first direction X, and at least part of the isolation units 31 are arranged side by side in the first direction X.

To improve display effect of the display panel, the light-emitting devices 200 are usually arranged according to specific rules to enhance display uniformity of the display panel. Furthermore, at least part of the light-emitting devices 200 will be arranged side by side in the first direction X. Specifically, the “at least part of the light-emitting devices 200 being arranged side by side in the first direction X” refers to that at least part of the light-emitting devices 200 are spaced apart from each other, and a line connecting centers of the light-emitting devices 200 are parallel to the first direction X. Light-emitting devices 200 of a same color may be arranged side by side in the first direction X, or light-emitting devices 200 of different colors may be arranged side by side in the first direction X, which is not limited in the present disclosure.

With reference to description mentioned above, with the isolation structure 300, the light-emitting device 200 may be formed by full-face evaporation and then the light-emitting material at certain locations may be removed through etching without need for a fine metal mask during the preparation process of the light-emitting device 200. Therefore, the isolation structure 300 has a significant influence on the preparation of the light-emitting device 200, and has a certain influence on relative position of the light-emitting devices 200.

On this basis, according an embodiment of the present disclosure, at least part of the isolation units 31 are arranged side by side in the first direction X to form the isolation structure 300, so that arrangement of the isolation units 31 follows the arrangement of at least part of the light-emitting devices 200, thereby making layout of the isolation units 31 more regular. Then, during the preparation process of the light-emitting devices 200, it helps to control at least part of the light-emitting devices 200 to be arranged side by side in the first direction X, thereby improving display uniformity of the display panel. In addition, the plurality of isolation units 31 are arranged side by side in the first direction X, which ensures that the first light-transmitting openings 302 may be ensured to be formed at gaps between the plurality of isolation units 31 in the first direction X, thereby improving transparent display effect. Meanwhile, the display panel may be stretched in the first direction X, thereby achieving a stretching effect.

In addition, in the embodiment of the present disclosure, since the plurality of isolation units 31 is spaced apart from each other, the isolation units 31 may also play a role in isolating water and oxygen from entering the light-emitting device 200 from a side, thereby providing encapsulation effect and protection effect for the light-emitting device 200 together with an encapsulation layer and improving the encapsulation effect for the light-emitting device 200.

All of the isolation units 31 may be arranged side by side in the first direction X. In one embodiment, only part of the isolation units 31 may be arranged side by side in the first direction X, while other isolation units 31 are arranged side by side in other directions, which is not limited in the present disclosure.

In some embodiments, the display function layer 24 may include a plurality of repeating units D, and the repeating unit D includes a plurality of light-emitting devices 200. At least part of the light-emitting devices 200 in a same repeating unit D are arranged side by side in the first direction X.

The plurality of repeating units D are translated and copied to form a pixel layout structure of the display panel, and a quantity, type, and relative position of the light-emitting devices 200 in each repeating unit D are the same. In one repeating unit D, light-emitting devices 200 of a same color are arranged side by side in the first direction X, or light-emitting devices 200 of different colors are arranged side by side in the first direction X.

Composition and arrangement of the light-emitting devices 200 in the repeating unit D are not limited in the present disclosure. The plurality of light-emitting devices 200 located within a dashed box shown in FIG. 20 refer to the plurality of light-emitting devices 200 located in a same repeating unit D. However, FIG. 20 does not constitute a limitation on the composition and arrangement of the light-emitting devices 200 in the repeating unit D. A specific structure of the repeating unit D needs to be determined according to an actual application requirement, which is not limited in the present disclosure.

Furthermore, since at least part of the light-emitting devices 200 and at least part of the isolation units 31 in a same repeating unit D are arranged along the first direction X, when the isolation structure 300 and the light-emitting devices 200 are designed, different light-emitting devices 200 in the same repeating unit D may be arranged in different isolation units 31, and at least part of isolation units 31, which are adjacent to each other, may be arranged side by side along the first direction X, so that at least part of the light-emitting devices 200 in the same repeating unit D are arranged side by side in the first direction X during the preparation of the light-emitting devices 200.

In other embodiments, the display function layer 24 may include the plurality of repeating units D, the repeating units D may include a plurality of light-emitting devices 200, and at least part of the plurality of repeating units D are arranged side by side in the first direction X.

Thus, when designing the isolation structure 300 and the light-emitting device 200, different light-emitting devices 200 in different repeating units D may be arranged in different isolation units 31, and at least part of the plurality of isolation units 31, which are adjacent to each other, may be arranged side by side along the first direction X, so that during the preparation of the light-emitting devices 200, at least part of the repeated units D may be arranged side by side in the first direction X.

Furthermore, in one embodiment, the plurality of light-emitting devices 200 within one repeating unit D is separately located in a plurality of isolation openings 301 of a same isolation unit 31.

Since a single isolation unit 31 itself is a continuous structure and is difficult to deform, the plurality of light-emitting devices 200 located within the same isolation unit 31 maintains a fixed relative position during a stretching process of the display panel. Based on this, according to the embodiment of the present disclosure, the plurality of light-emitting devices 200 within a same repeating unit D are disposed in a plurality of isolation openings 301 within the same isolation unit 31, thereby ensuring that a relative positional relationship between the light-emitting devices 200 within the same repeating unit D remains fixed during the stretching process of the display panel. Thus, light emission effect of each repeating unit D remains unchanged, thereby reducing risk of color deviation in a single repeating unit D and improving reliability of light emission of the repeating unit D.

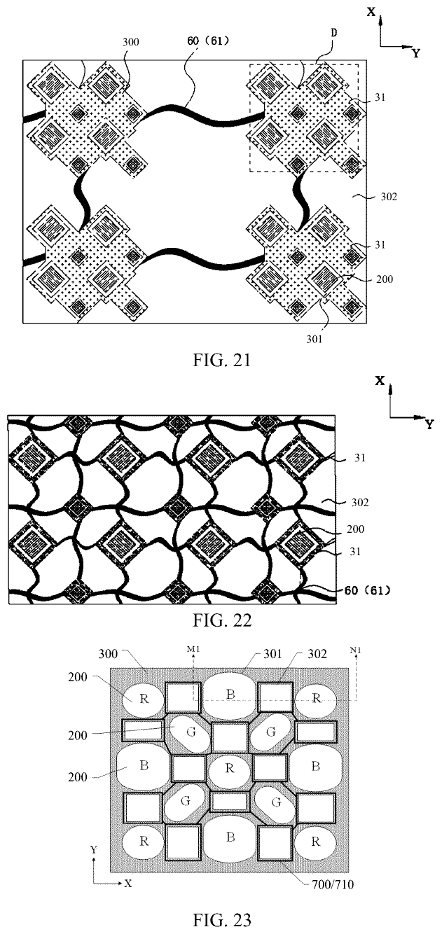

In some embodiments, referring to FIG. 21, part of the plurality of isolation units 31 are arranged side by side in a second direction Y, and the first direction X intersects with the second direction Y. For example, the first direction X is perpendicular to the second direction Y.

In the embodiment of the present disclosure, different isolation units 31 may be arranged side by side along the first direction X and the second direction Y respectively, so that the first light-transmitting openings 302 may be provided at different positions of the display panel in the first direction X and the second direction Y, which helps to improve the overall light transmittance rate of the display panel and further meet requirements of transparent display or photosensitive needs of the display panel. In addition, this design may allow stretching deformation of the display panel in at least the first direction X and the second direction Y, so that the size of the display panel and the stretching applicability are further increased.

In addition to the first direction X and the second direction Y, part of the plurality of isolation units 31 may also be arranged side by side in other directions depending on factors such as the stretching need of the display panel and arrangement requirement of the light-emitting devices 200 in the display function layer 24, which is not limited in the present disclosure.

In some embodiments, the display function layer 24 may include a plurality of repeating units D, and the repeating unit D may include a plurality of light-emitting devices 200. At least part of the plurality of light-emitting devices 200 in a same repeating unit D are arranged side by side in the second direction Y.

Since at least part of the plurality of light-emitting devices 200 and at least part of the plurality of isolation units 31 in a same repeating unit D are arranged along the second direction Y, when designing the isolation structure 300 and the light-emitting devices 200, different light-emitting devices 200 in a same repeating unit D may be arranged in different isolation units 31, and at least part of the plurality of isolation units 31, which are adjacent to each other, may be arranged side by side along the second direction Y, so that at least part of the plurality of light-emitting devices 200 in the same repeating unit D are arranged side by side in the second direction Y during the preparation of the light-emitting devices 200.

In some embodiments, the display function layer 24 may include the plurality of repeating units D, and the repeating unit D may include a plurality of light-emitting devices 200, and at least part of the plurality of repeating units D are arranged side by side in the second direction Y.

Thus, when designing the isolation structure 300 and the light-emitting device 200, different light-emitting devices 200 in different repeating units D may be arranged in different isolation units 31, and at least part of the plurality of isolation units 31, which are adjacent to each other, may be arranged side by side along the second direction Y, so that during the preparation of the light-emitting devices 200, at least part of the plurality of repeated units D are arranged side by side in the second direction Y.

In some embodiments, as shown in FIG. 22, different light-emitting devices 200 are disposed in different isolation units 31 respectively, that is, each isolation unit 31 is provided with only one isolation opening 301. For example, an orthographic projection of the isolation unit 31 on the substrate presents as an annular shape.

In this design, it may be ensured that there is a first light-transmitting opening 302 between any adjacent light-emitting devices 200, thereby further increasing a ratio of an area of the first light-transmitting opening 302 to an area of the display panel, and further improving transparent display effect or photosensitive effect of the display panel. In addition, during a stretching process of the display panel, it is possible to increase a relative distance between any two of the light-emitting devices 200, which helps to further improve an overall size of the stretched display panel, increase deformation of the display panel, and improve flexibility.

In at least one embodiment of the present disclosure, a shape of the isolation opening 301 (equivalent to a shape of a pixel) may be designed to increase a gap between the isolation openings without reducing an light-emitting area of the pixel (effective light-emitting area of the light-emitting unit) and pixels per inch (PPI), facilitating larger area of a light-transmitting opening. In the following, a detailed description is provided.

In at least one embodiment of the present disclosure, as shown in FIG. 23, at least two opposite ends of the isolation opening 301 are arc-shaped. In this design, a larger space between adjacent isolation openings 301 is reserved for designing a larger area of the first light-transmitting opening 302 while keeping the design area of the isolation opening 301 unchanged (the light-emitting area of the light-emitting unit remains unchanged) and the pixel density of the display panel unchanged, thereby further improving the light transmittance rate of the first region 13.

In at least one embodiment of the present disclosure, orthographic projections of the isolation opening 301 and the first light-transmitting opening 302 on the substrate are respectively conformal to a grid contour of an orthographic projection of a grid pattern on the substrate. In some embodiments, a shape of the first light-transmitting opening 302 is circular or rectangular. In one embodiment, an edge of the first light-transmitting opening 302 is conformal with an edge of an adjacent isolation opening 301. In some embodiments, at least two opposite ends of the first light-transmitting opening 302 are arc-shaped; and at least two opposite ends of the isolation opening 301 are arc-shaped.

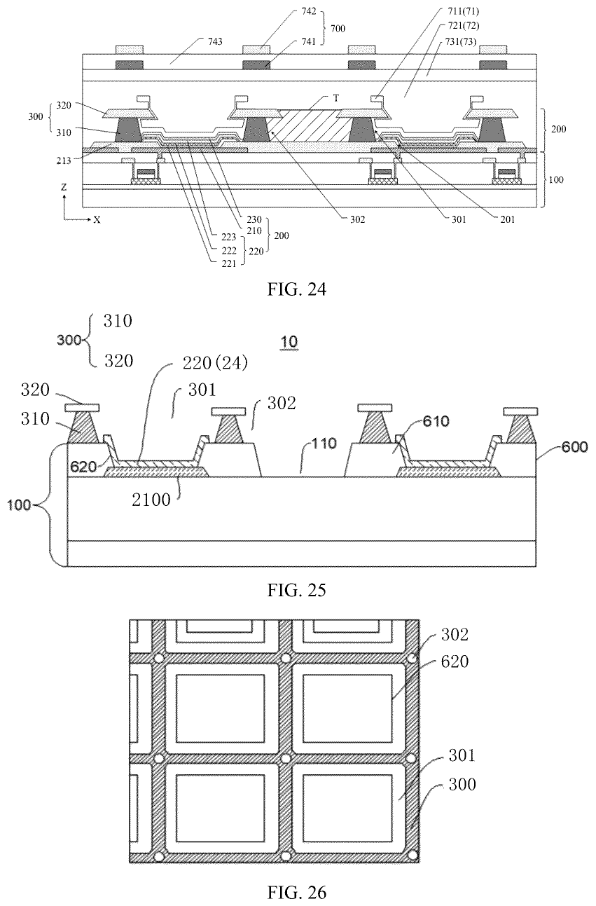

In at least one embodiment of the present disclosure, as shown in FIG. 24, the display panel may further include a first transparent filling portion T disposed within at least part of the first light-transmitting opening 302.

The first transparent filling portion T refers to a structure made of a material of a high light transmittance rate. Therein, the first transparent filling portion T is disposed within at least part of the plurality of first light-transmitting openings 302. The first transparent filling portion T may not have a significant impact the light transmittance rate of the first light-transmitting opening 302, thereby helping to achieve the transparent display effect. And the first transparent filling part T may also play a role in supporting an upper film layer, reducing difficulty in preparing the display panel and improving a preparation yield.

The composition of the material of the first transparent filling part T is not limited in the present disclosure. In one embodiment, the first transparent filling portion T may further include an elastic material. The elastic material may allow the display panel to be stretched. In one embodiment, the first transparent filling portion T may include an organic material.

In at least one embodiment of the present disclosure, as shown in FIGS. 1 to 5, the light-emitting device 200 may include a first electrode layer 2100 and a second electrode layer 2300 located on the substrate 100, and the light-emitting unit 220 is located between the first electrode layer 2100 and the second electrode layer 2300. The light-emitting unit 220 may include a first common layer 221, a light-emitting layer 222, and a second common layer 223 sequentially stacked on the first electrode layer 2100. The first common layer 221 may include a hole injection layer, a hole transport layer, an electron blocking layer, and so on. The second common layer 223 may include an electron injection layer, an electron transport layer, a hole blocking layer, and so on. The first common layer 221 (the main film layer causing current crosstalk) of each light-emitting device 200 may be electrically disconnected from each other with configuration of the isolation structure 300.

The first electrode layer 2100 is provided with a first electrode 210, and the second electrode layer 2300 is provided with a second electrode 230. A plurality of the second electrodes 230 are provided in the second electrode layer 2300, and the plurality of second electrodes 230 are disposed corresponding to the plurality of light-emitting units 220 respectively. The first electrode 210 and the second electrode 230 jointly drive and control light emission of the light-emitting unit 220. In one embodiment, the first electrode 210 is a cathode and the second electrode 230 is an anode. In one embodiment, the first electrode 210 is the anode and the second electrode 230 is the cathode.

In some embodiments, the second electrode 230 (such as the cathode) may be a transparent electrode. Furthermore, a material of the transparent electrode may include transparent metal oxide, including at least one of indium tin oxide (ITO), indium zinc oxide (IZO), aluminum zinc oxide (AZO), fluorine-doped tin oxide (FTO), silver-doped indium tin oxide, and silver-doped indium zinc oxide. In one embodiment, the second electrode 230 may be a three-layer structure. Therein, materials of the first layer and the third layer may include transparent metal oxide, including at least one of indium tin oxide (ITO), indium zinc oxide (IZO), and aluminum zinc oxide (AZO), and a material of the second layer in the middle may include metal, such as silver or copper. The first electrode 210 may be a reflective electrode or a transparent electrode, and the material of the reflective electrode includes silver, copper, or magnesium silver alloy. The light-emitting layer 222 may be an organic light-emitting layer. Therein, the organic light-emitting layer may only include a single-layer structure, for example, only includes an organic light-emitting material layer. In one embodiment, the organic light-emitting layer may also include a multi-layer structure, for example, include functional film layers such as a hole injection layer, a hole transport layer, an organic luminescent material layer, an electron transport layer, and an electron injection layer stacked in sequence from the second electrode 230 to the first electrode 210. A specific structure of the organic light-emitting layer is designed based on an actual application and is not specifically limited in the present disclosure. In one embodiment, the functional film layer of different light-emitting units 220 may be isolated from each other with the isolation structure 300, thereby reducing lateral crosstalk between the light-emitting units 220.

In at least one embodiment of the present disclosure, at least part of the isolation structure 300 is a conductive structure 32 (such as a first isolation layer 310 described below), and the conductive structure 32 is electrically connected to s second electrode 230 of an adjacent light-emitting device 200 and spaced apart from the first electrode 210. Thus, the second electrodes 230 of the plurality of light-emitting devices 200 may be electrically connected to each other through the conductive structure 32 of the isolation structure 300 to form a common electrode, so that a driving method of the second electrodes 230 of the current display panel (such as driving through one or a few common electrode lines) is still applicable.

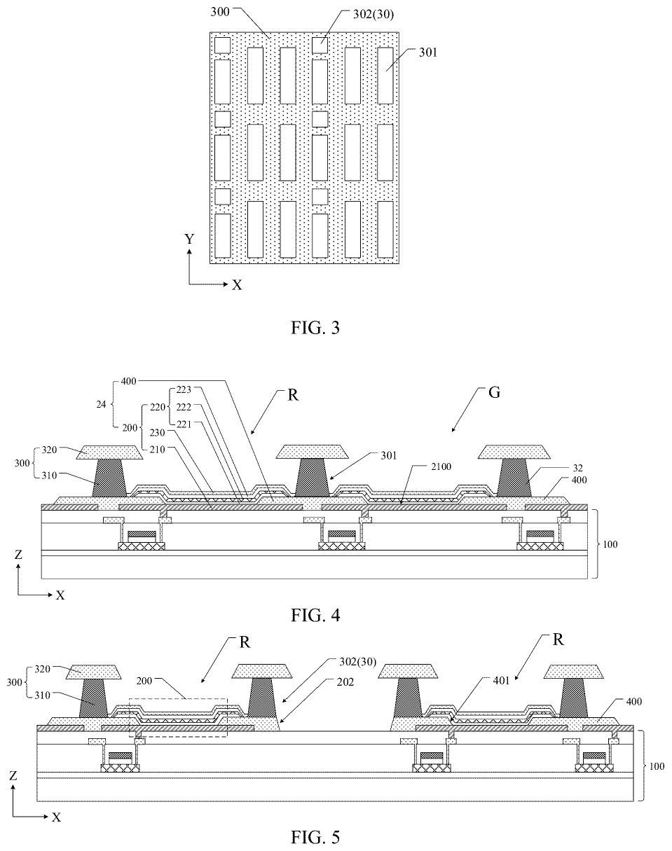

In an embodiment of the present disclosure, the isolation structure 300 may be designed to be wide at the top and narrow at the bottom, so that the first common layer 221 (the main film layer causing current crosstalk) is disconnected by the isolation structure 300 during evaporation. For example, as shown in FIG. 4 and FIG. 5, an orthographic projection of an end, closer to the substrate 100, of the conductive structure 32 of the isolation structure 300 on the substrate 100 is located within an orthographic projection of an end, away from the substrate 100, of the conductive structure 32 on the substrate 100.

In the embodiment of the present disclosure, while ensuring that the isolation structure layer is wide at the top and narrow at the bottom, a specific shape of the isolation structure layer is not further limited. In the following, several configuration of the isolation structure layer will be briefly described through embodiments.

For example, in some embodiments of the present disclosure, as shown in FIG. 4 and FIG. 5, the isolation structure 300 may include a first isolation layer 310 and a second isolation layer 320 stacked in layers. The first isolation layer 310 is located between the substrate 100 and the second isolation layer 320, and an orthographic projection of the first isolation layer 310 on the substrate 100 is located within an orthographic projection of the second isolation layer 320 on the substrate 100. The first isolation layer 310 is the conductive structure 32. For example, furthermore, along a direction perpendicular to the substrate 100, a cross-sectional shape of the first isolation layer 310 is a regular trapezoid. The second isolation layer 320 is located at a top side of the first isolation layer 310. In this case, evaporation material of the second electrode 230 may be deposited on a sidewall of the first isolation layer 310, thereby improving connection between the second electrode 230 and the first isolation layer 310.

In some embodiments of the present disclosure, the first isolation layer 310 may include a first end closer to the second isolation layer 320 and a second end further away from the second isolation layer 320. An orthographic projection of the first end is within an orthographic projection of the second end on the substrate 100. The orthographic projection of the first end on the substrate 100 being within the orthographic projection of the second end on the substrate 100 indicates that an area of the orthographic projection of the first end on the substrate 100 is less than an area of the orthographic projection of the second end on the substrate 100, and the orthographic projection of the second end on the substrate 100 covers the orthographic projection of the first end on the substrate 100.

In other embodiments of the present disclosure, the isolation structure 300 is an integrated structure. For example, furthermore, along the direction perpendicular to the substrate, a cross-sectional shape of the isolation structure 300 is an inverted trapezoid with a top side of the inverted trapezoid being closer to the substrate. In this design, the sidewall of the isolation structure 300 is a concave structure, thereby increasing isolation effect of the isolation structure 300.

For example, in the embodiment of the present disclosure, the conductive structure 32 is a metal conductive structure. A voltage drop may be reduced when the cathode is driven due to high conductivity of the metal material. Correspondingly, the metal material may allow light to transmit only when a thickness of the metal material is extremely thin. However, the isolation structure 300 requires a certain thickness to separate the light-emitting units. Therefore, the conductive structure 32 (such as the first isolation layer 310 below) in the isolation structure 300 is almost opaque. Therefore, only by setting the first light-transmitting opening 302 can light transmit through the isolation structure 300.

In some embodiments of the present disclosure, the material of the first isolation layer 310 may include transparent metal oxide. Therein, the transparent metal oxide includes at least one of indium tin oxide and indium zinc oxide.

In other embodiments of the present disclosure, the isolation structure 300 may further include a third isolation layer 33 disposed on a side, close to the substrate 100, of the first isolation layer 310. An orthographic projection of the third isolation layer 330 on the substrate 100 covers an orthographic projection of the first isolation layer 310 on the substrate 100. In one embodiment, the third isolation layer 330 includes a conductive structure 32. Specifically, the conductive structure 32 is located between the first isolation layer 310 and the substrate 100.

In at least one embodiment of the present disclosure, as shown in FIG. 4 and FIG. 5, the display function layer 24 may further include a pixel defining layer 400 located between the isolation structure 300 and the substrate 100. The pixel defining layer 400 includes a plurality of fourth openings 201 which are configured to define the light-emitting devices 200. The plurality of fourth openings 201 correspond to the plurality of isolation openings 301 respectively for exposing the first electrode 210. Thus, by setting the pixel defining layer 400, the conductive part of the isolation structure 300 may be separated from the first electrode 210, so that the first electrode 210 may have a larger design size to increase an area of a main light-emitting region of the light-emitting device 200 (equivalent to increasing a proportion of openings). It should be noted that the region where the fourth opening 201 is located represents the main light-emitting region of the light-emitting device.

For example, in some embodiments of the present disclosure, an orthographic projection of the isolation structure 300 on the substrate 100 coincides with an orthographic projection of the pixel defining layer 400 on the substrate 100, that is, the fourth opening 201 corresponds to the isolation opening 301 and an area of the fourth opening 201 is equal to an area of the isolation opening 301, so that the isolation structure 300 completely covers the gap between the light-emitting devices 200.

For example, in other embodiments of the present disclosure, the orthographic projection of the isolation structure 300 on the substrate 100 is located within the orthographic projection of the pixel defining layer 400 on the substrate 100, that is, the area of the fourth opening 201 is less than the area of the isolation opening 301, so that a light output angle of the light-emitting device is increased, thereby increasing a viewing angle of an image of the display panel.

In some embodiments of the present disclosure, in addition to the fourth opening 201, as shown in FIG. 5, the pixel defining layer 400 may further include a second through-hole 202. The second through-hole 202 is spaced apart from the fourth opening 201, and an orthographic projection of the second through-hole 202 on the substrate 100 overlaps with an orthographic projection of the first light-transmitting opening 302 on the substrate 100. The orthographic projection of the first light-transmitting opening 302 on the substrate 100 is located within the orthographic projection of the second through-hole 202 on the substrate 100. The light transmittance rate of the display panel at the first light-transmitting opening 302 may be further improved by this design, thereby enhancing transparent display effect. Furthermore, in one embodiment, at least part of the first transparent filling portion T may also be disposed within the second through-hole 202.

In some embodiments, at least part of the first isolation layer 310 of the isolation structure 300 may be located within the second through-hole 202 and covers at least part of a sidewall of the pixel defining layer 400.

In the embodiment of the present disclosure, at least part of the first isolation layer 310 extends into the second through-hole 202 and covers at least part of the sidewall of the pixel defining layer 400. This design allows the first isolation layer 310 to protect the sidewall, facing the second through-hole 202, of the pixel defining layer 400, thereby enhancing structural reliability of the display panel.

In at least one embodiment of the present disclosure, as shown in FIGS. 20 to 22, the display panel may further include a first wiring disposed on a side of the substrate 100, where at least part of an orthographic projection of the first wiring overlaps with an orthographic projection of the first light-transmitting opening 302 on the substrate 100.

Specifically, the first wiring may include a first signal line 60 disposed on a side of the substrate 100, and the first signal line 60 may include a curving segment 61. At least part of an orthographic projection of the curving segment 61 on the substrate 100 overlaps with the orthographic projection of the first light-transmitting opening 302 on the substrate 100.

The first signal line 60 and the isolation structure 300 are located on a same side of the substrate 100. The first signal line 60 may be disposed on a side, facing the substrate 100, of the isolation structure 300, or the first signal line 60 may be disposed in a same layer as part of structures of the isolation structure 300, which is not limited in the present disclosure. Meanwhile, types and overall extension direction of the first signal line 60 are not limited by the present disclosure. In one embodiment, the first signal line 60 may be a data line used for transmitting data signals. In one embodiment, the first signal line 60 may be a power line used for transmitting power signals to the first electrode 210 or the second electrode 230.

According to the content mentioned above, since the isolation units 31 are spaced apart from each other, when the display panel is stretched, a distance between adjacent isolation units 31 gradually increases, and a size of the entire display panel gradually increases. Based on this, in the embodiment of the present disclosure, the curving segment 61 is provided in the first signal line 60. Compared to a straight line structure, the curving segment 61 has a larger elongation under external forces and other factors, thereby meeting a stretching requirement of the display panel.

Furthermore, at least part of the orthographic projection of the curving segment 61 on the substrate 100 overlaps with the orthographic projection of the first light-transmitting opening 302 on the substrate 100, that is, the orthographic projection of the curving segment 61 on the substrate 100 is located between orthographic projections of adjacent isolation units 31 on the substrate 100. According to this design, when a distance between the adjacent isolation units 31 is gradually increased, the curving segment 61 may be deformed and gradually straightened with movement of the isolation units 31, thereby meeting the stretching requirement of the display panel. Therefore, risk of breakage of first signal line 60 due to the stretching of the display panel may be reduced, so that reliability of signal transmission inside the display panel may be improved.

A shape and size of the curving segment 61 are not specifically limited in the present disclosure. For example, the orthographic projection of the curving segment 61 on the substrate 100 may be an “S” shape. In the embodiment of the present disclosure, the first signal line 60 is electrically connected to the first isolation layer 310, so that specific signals in the first signal line 60 may be transmitted through the first isolation layer 310. The connection method between the first isolation layer 310 and the first signal line 60 is not limited in the present disclosure. For example, the first signal line 60 may be located on a side, facing the substrate 100, of the first isolation layer 310, and the first signal line 60 and the first isolation layer 310 are electrically connected to each other through a through-hole.

In some embodiments, the first signal line 60 and the first isolation layer 310 may be disposed in a same layer.

According to the content mentioned above, adjacent isolation units 31 are spaced apart from each other, and there is no film layer such as light-emitting unit 220 between the adjacent isolation units 31. Based on this, a supporting film layer may be filled between the adjacent isolation units 31, and then the first signal line 60 may be disposed on the supporting film layer, so that the first signal line 60 is located in the same layer as the first isolation layer 310 and electrically connected to the first isolation layer 310, thereby reducing occupation of the first signal line 60 on space of an array layer below and meeting wiring requirement of the display panel.

In some embodiments, the first signal line 60 may include a plurality of conductive segments spaced apart from each other, and the plurality of conductive segments are electrically connected to the first isolation layer 310.

In the embodiment of the present disclosure, the first signal line 60 and the first isolation layer 310 are located in the same layer and electrically connected with each other, so that the first signal line 60 is capable of transmitting signals through the first isolation layer 310. Based on this, the first signal line 60 may include a plurality of conductive segments spaced apart from each other, and adjacent conductive segments are capable of transmitting signals between each other through the first isolation layer 310. Furthermore, the conductive segments may include a curving segment 61 to meet the stretching requirement of the display panel.

Taking display panels shown in FIGS. 25 to 27 as an example, a detailed explanation of a specific structure of a display panel under another design provided in the present disclosure will be provided in the following.

In at least one embodiment of the present disclosure, as shown in FIG. 25 and FIG. 26, the display panel 10 may include: a substrate 100, provided with a second light-transmitting opening 110; an isolation structure 300 located on a side of the substrate 100, defining an isolation opening 301 and a first light-transmitting opening 302, where the second light-transmitting opening 110 is in communication with the first light-transmitting opening 302, and an orthographic projection of the second light-transmitting opening 110 on the substrate 100 is located within an orthographic projection of the first light-transmitting opening 302 on the substrate 100; and a display function layer 24 located on a side of the substrate 100, where the display function layer 24 includes a light-emitting device 220 located within the isolation opening 301.

In some embodiments, a shape of the orthographic projection of the first light-transmitting opening 302 on the substrate 100 is circular or square, making the shape of the first light-transmitting opening 302 more regular, so that a mask used for evaporation of the isolation structure 300 may be simple, facilitating the preparation of the mask, and reducing development difficulty.

In some embodiments, a plurality of second light-transmitting openings 110 are provided in the substrate 100. By providing the plurality of second light-transmitting openings 110, an overall light transmittance rate of the display panel 10 may be improved, thereby improving the performance of the display panel 10.

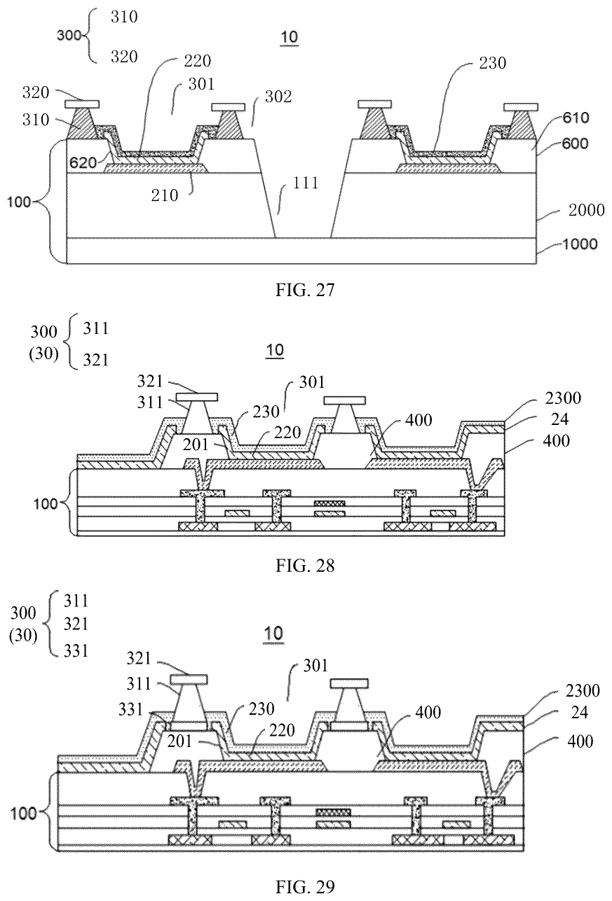

Referring to FIG. 27, FIG. 27 is a cross-sectional view of a partial region of a display panel according to yet still another embodiment of the present disclosure.

In some embodiments, as shown in FIG. 27, the substrate 100 may further include a base 1000 and an array layer 2000. The array layer 2000 is located on a side, close to the display function layer 24, of the base 1000. The second light-transmitting opening 110 may include a first through-hole 111 penetrating through the array layer 2000, so that the light transmittance rate of the display panel 10 at the second light-transmitting opening 110 may be improved.

In some embodiments, an orthographic projection of the first through-hole 111 on the substrate 100 is located within an orthographic projection of the first light-transmitting opening 302 on the substrate 100, and the first through-hole 111 is in communication with the first light-transmitting opening 302 completely, so that an area of an overlapping region between the orthographic projection of the first through-hole 111 on the substrate 100 and the orthographic projection of the first light-transmitting opening 302 on the substrate 100 is increased, that is, an area of a region with high light transmittance rate of the display panel 10 is increased, thereby improving an overall light transmittance rate of the display panel 10.

In some embodiments of the present disclosure, the array layer 2000 may include a plurality of wiring lines, and an orthographic projection of the plurality of wiring lines on the base 1000 is staggered with (non-overlapping) or partially overlapped with the orthographic projection of the first light-transmitting opening 302 on the base 1000. The partially overlapping means that the orthographic projection of the plurality of wiring lines on the base 1000 does not completely overlap with the orthographic projection of the first light-transmitting opening 302 on the base 1000, excluding a case where the orthographic projection of the plurality of wiring lines on the base 1000 coincides with the orthographic projection of the first light-transmitting opening 302 on the base 1000, and excluding a case where the orthographic projection of the plurality of wiring lines on the base 1000 completely covers the orthographic projection of the first light-transmitting opening 302 on the base 1000.

In addition, in some embodiments, the array layer 2000 may include a driving transistor, a source of the driving transistor receives a data driving signal, and a drain of the driving transistor is electrically connected to the second electrode 230. After a gate of the driving transistor receives a gate scan signal, the source and the drain of the driving transistor are turned on, and the source transmits the data driving signal to the second electrode 230 through the drain to drive the light-emitting device 200 to emit light through a voltage difference between the second electrode 230 and the first electrode 210. Of course, the array layer 2000 may also include other transistors and capacitors to realize signal transmission to the driving transistor, and so on.

In some embodiments of the present disclosure, an area of an orthographic projection of the light-transmitting portion on the substrate 100 is less than an area of an orthographic projection of the light-emitting device 200 on the substrate 10. Of course, this is not limited in the present disclosure, in other embodiments, the light transmittance rate of the display panel may also be improved by increasing the area of the orthographic projection of the light-transmitting portion on the substrate 100, such as making the area of the orthographic projection of the light-transmitting portion on the substrate 100 greater than or equal to the area of the orthographic projection of the light-emitting device 200 on the substrate 100, while maintaining a same pixel resolution.

In some embodiments of the present disclosure, at least part of an orthographic projection of the second electrode 230, such as an anode, on the substrate 100 overlaps with an orthographic projection of the driving transistor on the substrate 100, or at least part of an orthographic projection of the light-transmitting portion on the substrate 100 does not overlap with the orthographic projection of the driving transistor on the substrate 100, in order to prevent light from shining on the driving transistor through a reflection effect of the second electrode 230, such as the anode, and further prevent the driving transistor from affecting the light transmittance rate of the light-transmitting portion.

In some embodiments of the present disclosure, the array layer 2000 may further include a plurality of conductive layers stacked in layers and a first insulating layer located between adjacent conductive layers. The array layer 2000 is provided with a circuit structure to satisfy application requirements of the display panel. For example, the first signal line 60 may be disposed in the array layer 2000.

In some embodiments, the display panel 10 may further includes a second transparent filling portion, which fills the second light-transmitting opening 110. The second transparent filling portion is filled within the second light-transmitting opening 110, making the second light-transmitting opening 110 relatively flat for subsequent preparation of other film layers. The second transparent filling portion may include a transparent material, which ensures a high light transmittance rate at the second transparent opening 110 of the display panel 10 while flattening the display panel 10 at the second light-transmitting opening 110, thereby improving the performance of the display panel 10.

Taking display panels shown in FIGS. 28 to 30 as an example, a detailed explanation of the specific structure of a display panel under another design provided in the present disclosure will be provided in the following.

Referring to FIG. 28, FIG. 28 is a cross-sectional view of a partial region of a display panel according to yet still another embodiment of the present disclosure.

As shown in FIG. 28, the present disclosure provides a display panel 10. The display panel 10 includes a substrate 100, an isolation structure 300, and a display function layer 24. The isolation structure 300 is located on the substrate 100, and includes a light-transmitting portion 30 that defines an isolation opening 301. Furthermore, the light-transmitting portion 30 is made of a transparent material.

In some embodiments of the present disclosure, a light transmittance rate of the light-transmitting portion 30 under test light is greater than 0.6%. For example, the light transmittance rate of the light-transmitting portion 30 may be greater than 1%, 3%, 5%, 8%, 10%, 12%, 15%, 18%, 20%, or 25%. The light transmittance rate of the light-transmitting portion 30 under visible light is greater than 30%. In one embodiment, the light transmittance rate of the light-transmitting portion 30 under visible light is greater than 50%. In one embodiment, the light transmittance rate of the light-transmitting portion 30 under visible light is greater than 60%. In one embodiment, the light transmittance rate of the light-transmitting portion 30 under visible light is greater than 70%, so that the display panel meets requirements for light transmittance rate in scenes such as under-screen fingerprints and under-screen cameras. Therein the test light may be visible light or near-infrared light, and a wavelength of the test light may be 550 nm or 940 nm.

In some embodiments of the present disclosure, the isolation structure 300 may include a first transparent layer 311 and a second transparent layer 321 stacked in sequence along a thickness direction. The second transparent layer 321 is located on a side, away from the substrate 100, of the first transparent layer 311, and an orthographic projection of the first transparent layer 311 on the substrate 100 is located within an orthographic projection of the second transparent layer 321 on the substrate 100. The display function layer 24 includes a plurality of light-emitting units 220 spaced apart from each other and each of the plurality of light-emitting units 220 is located in an isolation opening 301.

According to the display panel 10 provided by the embodiment of the present disclosure, the display panel 10 includes the substrate 100, the isolation structure 300, and the display function layer 24. The isolation structure 300 is disposed on the substrate 100 and defines a plurality of isolation openings 301. The isolation structure 300 includes the first transparent layer 311 and the second transparent layer 321, and the orthographic projection of the first transparent layer 311 on the substrate 100 is located within the orthographic projection of the second transparent layer 321 on the substrate 100, so that sidewall of the first transparent layer 311 is concave relative to sidewall of the second transparent layer 321, thereby separating the display function layer 24 to form the plurality of light-emitting units 220 mutually disconnected. Therefore, crosstalk of carriers in the display function layer 24 may be reduces and development and use of fine masks may also be reduced, thereby reducing a preparation cost. The light-emitting unit 220 is located within the isolation opening 301 to achieve light-emitting display. The first transparent layer 311 and the second transparent layer 321 have a high light transmittance rate. When the display panel 10 is provided with a photosensitive component, photosensitive effect of the photosensitive component may be improved with the transparent isolation structure 300.

Referring to FIG. 29, FIG. 29 is a cross-sectional view of a partial region of a display panel according to yet still another embodiment of the present disclosure.

As shown in FIG. 29, in some embodiments, the isolation structure 300 may further include a third transparent layer 331 located on a side, close to the substrate 100, of the first transparent layer 311.

In some embodiments of the present disclosure, the third transparent layer 331 may also have a high light transmittance rate, thereby ensuring transparency of the isolation structure 300. The third transparent layer 331 is located between the first transparent layer 311 and the substrate 100. When the first transparent layer 311 is etched, the third transparent layer 331 has a certain protection effect on the substrate 100, preventing entry of etching waste from the first transparent layer 311 into the substrate 100 and solving a problem of the substrate 100 being easily eroded by the etching waste.

In some embodiments, the display panel 10 may further include a second electrode layer 2300, and the second electrode layer 2300 is located on a side, away from the substrate 100, of the display function layer 24. The second electrode layer 2300 includes a plurality of second electrodes 230 spaced apart from each other and each of the plurality of second electrodes 230 is located in an isolation opening 301. The third transparent layer 331 includes a conductive material, and the second electrode 230 and the third transparent layer 331 are electrically connected.

In some embodiments of the present disclosure, the second electrode layer 2300 is disconnected by the isolation structure 300 to form the plurality of second electrodes 230 located within the isolation openings 301. The second electrodes 230 are electrically connected to the third transparent layer 331, so that the second electrodes 230 spaced apart are electrically connected to each other through the isolation structure 300 to form a full-surface electrode.

In one embodiment, the third transparent layer 331 may include a transparent conductive layer. Therefore, the third transparent layer 331 may have a high light transmittance rate and good conductivity, thereby increasing the light transmittance rate of the display panel 10 while ensuring that the second electrodes 230 are electrically connected to each other through the third transparent layer 331.

In one embodiment, each of the second transparent layer 321 and the third transparent layer 331 includes at least one of indium tin oxide (ITO) and indium zinc oxide (IZO). The indium tin oxide (ITO) and the indium zinc oxide (IZO) have a high light transmittance rate and high conductivity, increasing the light transmittance rate of the display panel 10 while ensuring that the second electrodes 230 are electrically connected to each other through the third transparent layer 331.

In one embodiment, the third transparent layer 331 may include a transparent metal layer, which increases the light transmittance rate of the display panel 10 while ensuring that the second electrodes 230 are electrically connected to each other through the third transparent layer 331. For example, the third transparent layer 331 may include a silver metal layer with a smaller thickness.

In one embodiment, the first transparent layer 311 may include an inorganic transparent layer, for example, the first transparent layer 311 may include silicon nitride (SiN) or silicon oxide (SiO). The first transparent layer 311 includes an inorganic light-transmitting material, which increases the light transmittance rate of the display panel 10. Meanwhile, the first transparent layer 311 made of the inorganic material may be etched through different etching methods compared to the second transparent layer 321 and the third transparent layer 331, so that the first transparent layer 311 may be etched separately, which makes the sidewall of the first transparent layer 311 be concave relative to the second transparent layer 321, thereby realizing isolation between the display function layer 24 and the second transparent layer 321.

In one embodiment, the first transparent layer 311 may include a transparent metal layer. For example, the first transparent layer 311 may include a silver (Ag) thin film. The first transparent layer 311 also has a high light transmittance rate and good conductivity. The second electrodes 230 may be electrically connected to each other either through the third transparent layer 331 or through the first transparent layer 311. When the isolation structure 300 only includes the first transparent layer 311 and the second transparent layer 321, the first transparent layer 311 includes a transparent conductive layer, and the second electrodes 230 are electrically connected to the first transparent layer 311 to achieve mutual electrical connection between the second electrodes 230.

In one embodiment, the second transparent layer 321 may include a transparent metal layer. Both the second transparent layer 321 and the third transparent layer 331 are the transparent metal layers, further improving the light transmittance rate of the display panel 10.

In one embodiment, a cross-sectional shape of the first transparent layer 311 along the thickness direction of the display panel 10 may be a trapezoid. When the cross-sectional shape of the first transparent layer 311 is trapezoidal, on one hand, the second transparent layer 321 may be stably supported, and on the other hand, the sidewall of the first transparent layer 311 is configured to be concave relative to the second transparent layer 321, realizing disconnection between the second electrodes 230 at a position of the isolation structure 300.

In some embodiments, an orthographic projection of the first transparent layer 311 on the substrate 100 is located within an orthographic projection of the third transparent layer 331 on the substrate 100.

In these embodiments, the orthographic projection of the first transparent layer 311 on the substrate 100 is located within the orthographic projection of the third transparent layer 331 on substrate 100. That is, a bottom surface, closer to the substrate 100, of the first transparent layer 311 is totally over the third transparent layer 331. A sidewall, facing the isolation opening 301, of the first transparent layer 311 is concave relative to that of the third transparent layer 331. When preparing the second electrode 230, an edge of the third transparent layer 331 protrudes from the first transparent layer 311, which increases a contact area between the third transparent layer 331 and the second electrode 230, thereby improving connection performance between the second electrode 230 and the third transparent layer 331.

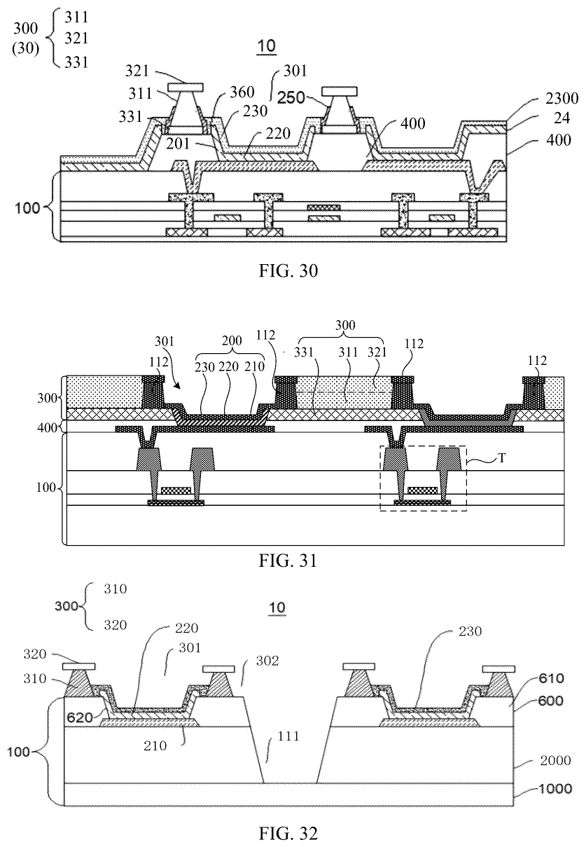

As shown in FIG. 30, FIG. 30 is a cross-sectional view of a partial region of a display panel according to yet still another embodiment of the present disclosure. In some embodiments, the display panel 10 includes a connection portion 250, which is connected to a sidewall, facing the isolation opening 301, of the isolation structure 300 and electrically connected to the third transparent layer 331. The connection portion 250 is electrically connected to the second electrode 230.

In these embodiments, the connection portion 250 is provided on the sidewall, facing the isolation opening 301, of the isolation structure 300, so that the third transparent layer 331 and the second electrode 230 are electrically connected to each other through the connection portion 250 to improve the connection performance between the second electrode 230 and the third transparent layer 331.

In one embodiment, the connection portion 250 is connected to a sidewall, facing the isolation opening 301, of the third transparent layer 331, so that the third transparent layer 331 is electrically connected to the second electrode 230 through the connection portion 250.

In one embodiment, the connection portion 250 is connected to both the sidewalls, facing the isolation opening 301, of the first transparent layer 311 and the third transparent layer 331. When both the first transparent layer 311 and the third transparent layer 331 are made of conductive materials, the second electrode 230 is connected to both the first transparent layer 311 and the third transparent layer 331 through the connection portion 250, further improving the connection performance between the second electrode 230 and the isolation structure 300.

In one embodiment, the connection portion 250 may include a transparent metal material, allowing the second electrode 230 to be connected to the isolation structure 300 while also improving the light transmittance rate of the display panel 10. In some embodiments, the light-emitting unit 220 is spaced apart from the isolation structure 300.

In these embodiments, the light-emitting units 220 are spaced apart from the isolation structure 300, making it difficult for the light-emitting units 220 to be electrically connected to each other through the isolation structure 300, further reducing crosstalk of carriers between the light-emitting units 220.

In some embodiments, the light-emitting unit 220 is spaced apart from the isolation structure 300 to form a gap 360, and a part of the connection portion 250 is located within the gap 360.

In these embodiments, when preparing the connection portion 250, a part of the connection portion 250 is deposited into the gap 360 to fill the gap 360 and contacts with the third transparent layer 331, improving the connection performance between the connection portion 250 and the third transparent layer 331.

As shown in FIG. 31, FIG. 31 is a cross-sectional view of a partial region of a display panel according to yet still another embodiment of the present disclosure. The isolation structure 300 may further include an opaque portion 112, which partially surrounds the light-transmitting portion 30.

In some embodiments, the opaque portion 112 only surrounds the first transparent layer 311 and the second transparent layer 321, and does not surround the transparent conductive layer in the third transparent layer 331, so that the transparent conductive layer is electrically connected to the second electrode 230. Of course, this is not limited in the present disclosure, in other embodiments, the opaque portion 112 may only surround part of the sidewall of the light-transmitting portion 30 such as the first transparent layer 311, the second transparent layer 321, and the third transparent layer 331, so that sidewall exposed may make transparent conductive layer be electrically connected to the second electrode 230.

In some embodiments, as shown in FIG. 32, the substrate 100 may further include a second insulation layer 600. The second insulation layer 600 includes a cover portion 610 and a third through-hole 620 defined by the cover portion 610. The cover portion 610 covers sidewall of the first electrode 210, and part of the first electrode 210 is exposed by the third through-hole 620. The third through-hole 620 is in communication with to the isolation opening 301.

In some embodiments, the second electrode 230 is exposed by the third through-hole 620. One of the second electrode 230 and the first electrode 210 serves as an anode of the light-emitting unit 220, while the other serves as a cathode of the light-emitting unit 220. This embodiment takes the second electrode 230 as the anode of the light-emitting unit 220 and the first electrode 210 as the cathode of the light-emitting unit 220 for example. The cover portion 610 of the second insulation layer 600 is configured to define the third through-hole 620 to arrange the light-emitting unit 220 and allow the light emitted by the light-emitting unit 220 to transmit through the second insulation layer 600. And the cover portion 610 is configured to define an arrangement region for the light-emitting unit 220, reducing color crosstalk between the light-emitting units 220. The cover portion 610 covers the surface of the sidewall of the first electrode 210 to achieve insulation wrapping of the surface of the sidewall of the first electrode 210 by the cover portion 610, so that invasion of moisture through the cover portion 610 is reduced and service life of the display panel 10 is prolonged.

As shown in FIG. 32, in some embodiments, the isolation structure 300 is located on the cover portion 610. In these embodiments, the isolation structure 300 is disposed on the cover portion 610, and there is a large height difference between the isolation structure 300 and the third through-hole 620. When preparing the display function layer 24, due to the large height difference, the display function layer 24 is more easily separated at the position of the isolation structure 300, thereby reducing difficulty in preparing the display function layer 24.

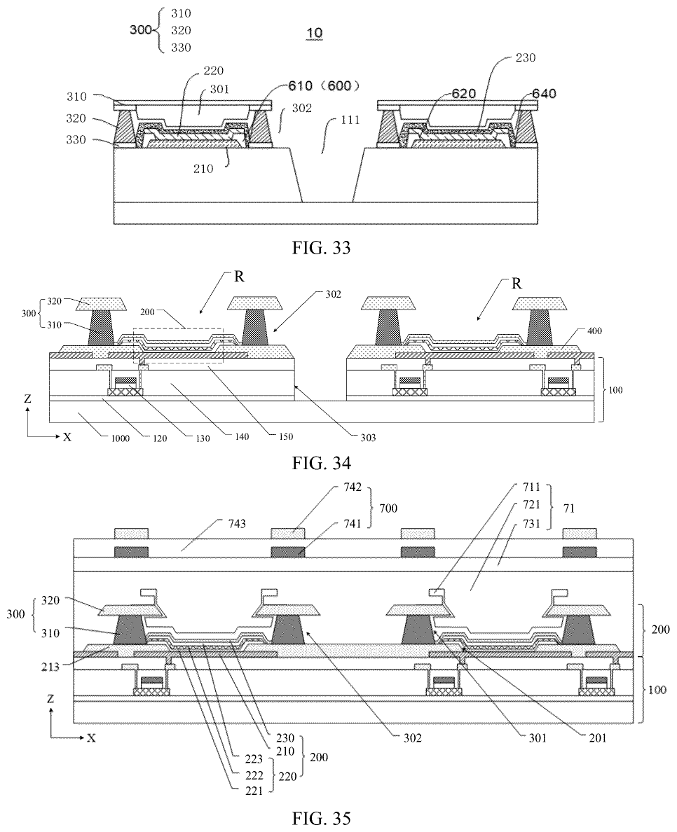

As shown in FIG. 33, in some embodiments, the isolation structure 300 is located on the cover portion 610.

In these embodiments, an accommodation opening 640 is provided on the cover portion 610, and the isolation structure 300 is located within the accommodation opening 640. As the isolation structure 300 is disposed in the accommodation opening 640 on the cover 610, in the preparation process, the isolation structure 300 is prepared before the preparation of the first electrode 210. That is, after the isolation structure 300 is prepared on the substrate 100, the first electrode 210 is prepared on the substrate 100, so that an impact of the preparation of the isolation structure 300 on the first electrode 210 is reduced, ensuring that the first electrode 210 is not damaged.

In some embodiments, a plurality of cover portions 610 are provided in the second insulation layer 600. Each cover portion 610 covers the sidewall of the first electrode 210 and is configured to be in an annular shape surrounding the sidewall of the first electrode 210. The isolation structure 300 may be disposed between adjacent cover portions 610. As the isolation structure 300 is arranged at a gap between adjacent cover portions 610, in the preparation process, the isolation structure 300 is prepared before the preparation of the first electrode 210. That is, after the isolation structure 300 is prepared on the substrate 100, the first electrode 210 is prepared on the substrate 100, so that the impact of the preparation of the isolation structure 300 on the first electrode 210 is reduced, ensuring that the first electrode 210 is not damaged. And the plurality of cover portions 610 are spaced apart, making it difficult for moisture to invade between cover portions 610, thereby prolonging the service life of the display panel 10.

In some embodiments, the second insulation layer 600 may include a pixel defining layer 400. In one embodiment, the second insulation layer 600 is reused as the pixel defining layer 400, the cover portion 610 is reused as a pixel defining portion, the third through-hole 620 is reused as a fourth opening 201, and the isolation structure 300 is located on a side, away from the substrate 100, of the pixel defining portion. In these embodiments, the isolation structure 300 is disposed on the pixel defining portion, and the isolation structure 300 is equivalent to a pixel opening with a large height difference. When preparing the display function layer 24, due to the large height difference, the display function layer 24 is more easily separated at the position of the isolation structure 300, reducing difficulty in preparing the display function layer 24.

In one embodiment, the second insulation layer 600 may include organic material and/or inorganic material. When the second insulation layer 600 includes the inorganic material, the second insulation layer 600 may have higher density and better encapsulation performance.

In some embodiments, the substrate 100 may include a base and a driving circuit layer located on the base. The driving circuit layer may include a plurality of pixel driving circuits located in the second region 11, and the display function layer 24 is located on the driving circuit layer. For example, a pixel driving circuit may include a plurality of transistors (TFTs), capacitors, and so on to form various forms such as 2TIC (that is, 2 transistors (TFTs) and 1 capacitor (C)), 3TIC, or 7TIC. The pixel driving circuit is connected to the light-emitting device 200 to control an on/off state and brightness of the light-emitting device 200.

For example, as shown in FIG. 34, the substrate 100 may include an base 1000 for carrying the driving circuit layer; and the substrate 100 may further include a buffer layer 120 located between the driving circuit layer and the base 1000, and the buffer layer 120 is used for isolating harmful ions (such as hydrogen ions, and so on) from the base 1000. The driving circuit layer may further include a plurality of insulation film layers of various structures (such as a signal line, an electrode of the capacitor, an active layer in TFT, a source drain electrode, a gate electrode, and so on) for defining the driving circuit, and the plurality of insulation film layers may include a gate insulation layer 130, an interlayer dielectric layer 140, a planarization layer 150, and so on.

In the embodiment of the present disclosure, the first light-transmitting opening 302 may be deepened to increase the light transmittance rate of the first display region 13, that is, at least one of the pixel defining layer, the substrate, the buffer layer, the gate insulation layer, the interlayer dielectric layer, and the planarization layer is provided with a through-hole, and the through-hole corresponds to the first light-transmitting opening 302 and is in communication with the first light-transmitting opening 302. For example, as shown in FIG. 34, the pixel defining layer 400, the buffer layer 120, the gate insulation layer 130, the interlayer dielectric layer 140, and the planarization layer 150 are provided with a through-hole 303. The through-hole 303 corresponds to the first light-transmitting opening 302 and communicates with the first light-transmitting opening 302, that is, the arrangement of the through-hole 303 is equivalent to increasing the depth of the first light-transmitting opening 302.

In the embodiment of the present disclosure, a plurality of through-holes may be provided, and a depth of the through-hole at different positions may be configured to be the same or different. For example, a depth of some through-holes may extend to penetrate through the substrate, and a depth of some through-holes may only penetrate through the pixel defining layer 400. In addition, in a case where a plurality of first light-transmitting openings 302 are provided, the through-holes may be configured to be disposed under each of the plurality of first light-transmitting opening 302, or may be configured to be disposed under part of the plurality of first light-transmitting opening 302. In addition, in a case where the first light-transmitting opening 302 is configured to be in a grid shape, the through-holes are not limited to be in a grid shape. For example, the through-holes may be configured to be in a grid shape, and the grid shaped through-holes are configured to penetrate through the pixel defining layer 400, or through the pixel defining layer 400 and the planarization layer 150 to avoid impact of the through-hole on circuit structures in the driving circuit layer. In one embodiment, a plurality of through-holes may be configured to be dispersedly disposed below the grid-shaped first light-transmitting opening 302.

In at least one embodiment of the present disclosure, as shown in FIG. 35, the display panel 10 may further include a protection layer 800, and the protection layer 800 at least covers the light-emitting device 200 to protect film layers of the light-emitting device 200 during the preparation process of the display panel. The light-emitting devices 200 emitting light of different colors are independently prepared. However, the film layers (such as the light-emitting unit) of the light-emitting device 200 are prepared through a full-surface evaporation on the display panel. For example, the light-emitting devices 200 may be divided into light-emitting devices that respectively emit red light (R), green light (G), and blue light (B). During the preparation process, the light-emitting devices R, G, and B are sequentially prepared. When preparing the light-emitting device R, a light-emitting device R is formed in each isolation opening, and a protection layer 800 is prepared on the display panel to cover the light-emitting device R. Then, the protection layer 800 in some other isolation openings (used for forming light-emitting devices G and B in a final product), as well as the cathode and light-emitting unit of the light-emitting device R, are removed. In this process, the protection layer 800 is used for protecting the light-emitting devices R in other isolation openings. Based on this method, the light-emitting devices G and B are sequentially prepared, and finally the protection layer 800 as shown in FIG. 35 are formed.

The protection layer plays a role of encapsulating the light-emitting devices, so the protection layer may also be referred to as an encapsulation layer (when only one film layer is provided) or one of encapsulation layers (when several encapsulation film layers are provided).

In at least one embodiment of the present disclosure, as shown in FIG. 23, the display panel 10 may further include a touch electrode layer 700.

The touch electrode layer 700 includes a plurality of touch electrode blocks 710, and the touch electrodes 710 are connected to each other to form a grid pattern with mesh holes. Correspondingly, the mesh holes of the grid pattern are defined by the plurality of touch electrode blocks 710 connected to each other. The mesh holes of the grid pattern respectively correspond to the plurality of isolation openings 301 and the plurality of first light-transmitting openings 302. Orthographic projections of the isolation opening 301 and the first light-transmitting openings 302 on the substrate 100 overlap with at least part of orthographic projections of corresponding mesh holes on the substrate 100.

In at least one embodiment of the present disclosure, as shown in FIG. 23 and FIGS. 35 to 38, the touch electrode layer 700 may include a plurality of paralleled first touch electrodes 741 and a plurality of paralleled second touch electrodes 742. The first touch electrode 741 includes a plurality of touch electrode blocks 710 connected to each other along a row direction (X-axis direction in FIG. 37), and the second touch electrode 742 includes a plurality of touch electrode blocks 710 connected to each other along a column direction (Y-axis direction in FIG. 37). The first touch electrode 741 and the second touch electrode 742 are spaced apart from each other and orthographic projections of the first touch electrode 741 and the second touch electrode 742 intersect with each other to form a touch unit at the intersection. Meanwhile, the first touch electrode 741 and the second touch electrode 742 are arranged in a grid pattern.

For example, in some embodiments of the present disclosure, as shown in FIG. 37 and FIG. 38, the first touch electrode 741 is located between the second touch electrode 742 and the isolation structure 300. For example, a first conductive material layer may be deposited first and then etched to form the plurality of first touch electrodes 741. Therein, a plurality of mesh holes are formed in the first conductive material layer so that the first touch electrodes 741 may be formed into a grid pattern. A touch insulation layer 743 is deposited on the first touch electrodes 741 to cover the first touch electrodes 741. A second conductive material layer is deposited on the touch insulation layer 743 and patterned to form the plurality of second touch electrodes 742. Therein, a plurality of mesh holes are formed in the second conductive material layer so that the second touch electrodes 742 is formed into a grid pattern. On a macro level, a region where the first touch electrode 741 and the second touch electrode 742 intersect and overlap is an region where the touch unit is located. Meanwhile, at the position of intersection, both the first touch electrode 741 and the second touch electrode 742 appear transparent.

For example, in the structures shown in FIG. 37 and FIG. 38, orthographic projections of the mesh holes in the first touch electrode 741 on the substrate 100 partially coincides with orthographic projections of the mesh holes in the second touch electrode 742 on the substrate 100, so that a light transmittance rate of the touch electrode layer 700 may be improved.

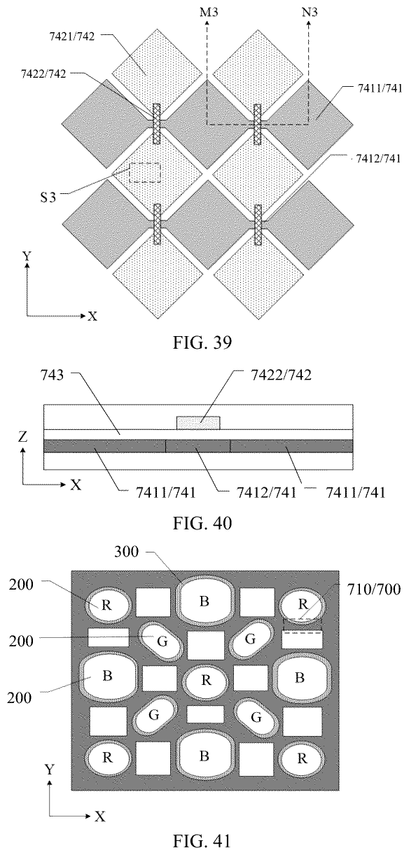

For example, in other embodiments of the present disclosure, as shown in FIG. 39 and FIG. 40, the first touch electrode 741 includes a plurality of first sub touch electrodes 7411 that are spaced apart from each other and a plurality of first connection portions 7412. The plurality of first sub touch electrodes 7411 of a same first touch electrode 741 are connected through the first connection portions 7412. The second touch electrode 742 includes a plurality of second sub touch electrodes 7421 that are spaced apart from each other and a plurality of second connection portions 7422. The plurality of second sub touch electrodes 7421 of a same second touch electrode 742 are connected through the second connection portions 7422. The first connection portions 7412 and the second connection portions 7422 intersect with each other and are spaced apart from each other. Therein, the first sub touch electrodes 7411, the first connection portions 7412, and the second touch electrode 742 are located in a same layer, and the second connection portions 7422 are located between the first connection portions 7412 and the isolation structure 300. In one embodiment, the second connection portions 7422 are located on a side, away from the isolation structure 300, of the first connection portions 7412. In this design, the touch electrode layer 700 may have a high light transmittance rate, and alignment accuracy between the mesh holes and the isolation openings 301 and the first light-transmitting openings 302 may be improved, thereby improving the light transmittance rate of the first region 13. For example, a first conductive material layer may be deposited first and then patterned to form the plurality of first touch electrodes 741 and the plurality of second sub touch electrodes 7421 of the second touch electrodes 742. Therein, a plurality of mesh holes are formed in the first conductive material layer, so that the plurality of first touch electrodes 741 and the plurality of second sub touch electrodes 7421 of the second touch electrodes 742 may be formed into a grid pattern. A touch insulation layer 743 is then deposited to cover the first touch electrodes 741 and the plurality of second sub touch electrodes 7421 of the second touch electrodes 742. The touch insulation layer 743 is patterned to form through-holes exposing the second sub touch electrodes 7421. A second conductive material layer is deposited on the touch insulation layer 743 and patterned to form a plurality of second connection portions 7422 of the second touch electrodes 742, where the second connection portions 7422 are connected to the second sub touch electrodes 7421 through the through-holes. In this design, the first touch electrodes 741 and main body of the second touch electrodes 742 are designed to be located in the same layer, so that there is no need to consider alignment of their mesh holes, which is beneficial for improving the light transmittance rate of the touch electrode layer 700.

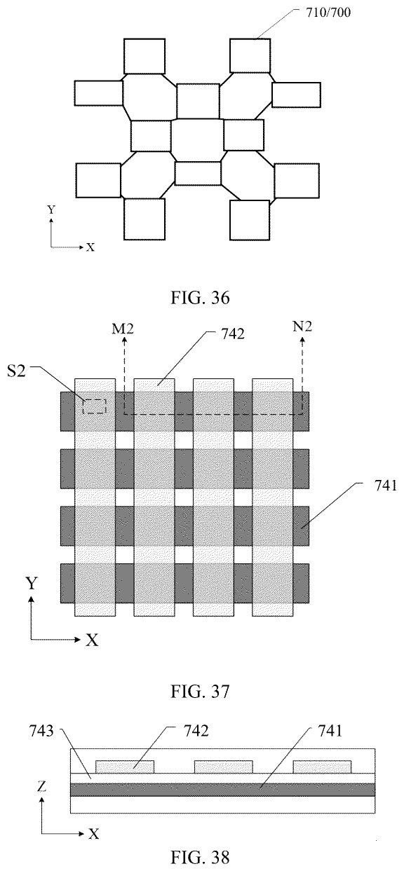

In at least one embodiment of the present disclosure, referring back to FIG. 23, FIG. 35 and FIG. 36, a width of the grid patterned touch electrode block 710 needs to be designed to be less than spacing between the light-emitting units 220, that is, an orthographic projection of the grid patterned touch electrode block 710 on the substrate 100 is located within the orthographic projection of the isolation structure 300 on the substrate 100, so that the orthographic projections of the isolation opening 301 and the first light-transmitting opening 302 on the substrate 100 is located within orthographic projections of corresponding mesh holes on the substrate 100. By this design, light emitted from the display panel may have a larger emission angle, so that the display panel has a larger viewing angle.

In at least one embodiment of the present disclosure, referring back to FIG. 23, FIG. 35 and FIG. 36, distances from the grid patterned touch electrode block located between adjacent two isolation openings 301 to the two adjacent isolation openings 301 are equal. For the grid patterned touch electrode block located between adjacent two isolation openings 301 and the adjacent two isolation openings 301, minimum distances from an orthographic projection of any point on the touch electrode block on the substrate to the orthographic projections of the isolation openings 301 on the substrate is equal; and/or, the distance from a grid patterned touch electrode block, located between the isolation opening 301 and a first light-transmitting opening 302 adjacent to the isolation opening 301, to the isolation opening 301 is equal to a distance from the grid patterned touch electrode block to the first light-transmitting opening 302. For the adjacent isolation openings 301 and the first light-transmitting opening 302, as well as the grid patterned touch electrode block located between the adjacent isolation openings 301 and the first light-transmitting opening 302, minimum distances from any point of the orthographic projection of the touch electrode block on the substrate to the orthographic projections of the isolation openings 301 and the first light-transmitting opening 302 on the substrate is equal. By this design, maximum viewing angles of the light-emitting unit in different directions may be approximately equal, thereby relieving a phenomenon of color deviation.

For example, in some embodiments of the present disclosure, the grid patterned touch electrode block 710 is designed as a structure composed of lines as shown in FIG. 23, FIG. 35 and FIG. 36. Such structure may be composed of straight and curving segments connected to each other, and a width of each part of the straight and curving segments is basically equal. For example, ‘distance from the touch electrode block to the isolation openings 301 being equal’ may be understood as: a minimum distance from any point on the touch electrode block to an adjacent isolation opening 301 is equal. That is, the touch electrode block is located on a center boundary line of the adjacent isolation openings 301.

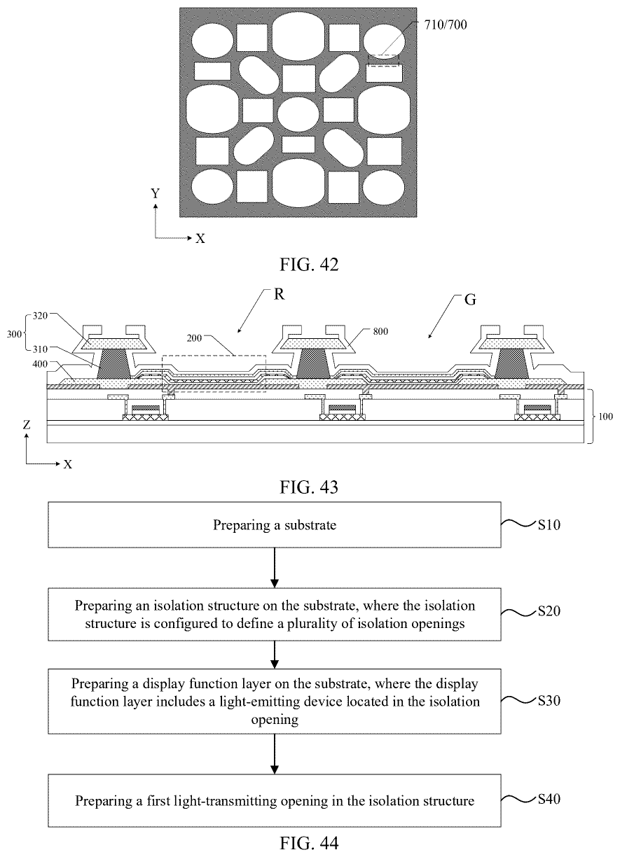

For example, in other embodiments of the present disclosure, as shown in FIG. 41 and FIG. 42, the mesh hole defined by the grid patterned touch electrode blocks 710 is conformal with a corresponding isolation opening or a corresponding first light-transmitting opening, so that a minimum distance from different points of the orthographic projection of the touch electrode blocks 710 that defined a same mesh hole on the substrate to the orthographic projection of the isolation opening or the first light-transmitting opening on the substrate is equal. A shape of the touch electrode block 710 is shown in FIG. 42. In this case, in order to ensure the viewing angle of the display panel, an edge of the mesh hole is configured to have a first distance from the edge of the corresponding isolation opening, and the first distance may be a preset value, so that the maximum viewing angle of the light-emitting units in all directions is approximately equal.

In the embodiment of the present disclosure, the display panel 10 may further include an encapsulation layer covering the display function layer 24, the encapsulation layer is configured to isolate the light-emitting devices 200 in the display function layer 24 and has a planarization function so that a touch functional layer, a polarizer, a lens layer, a cover plate, and other functional structures may be provided on the encapsulation layer. For example, the encapsulation layer may include a first inorganic encapsulation layer, an organic encapsulation layer, and a second inorganic encapsulation layer sequentially stacked on the display function layer 24. The first inorganic encapsulation layer and second inorganic encapsulation layer have high density to isolate water and oxygen, and the organic encapsulation layer has a larger thickness and planarization function. For example, in a case where the protection layer mentioned above is provided in the display panel, the protection layer may be independently disposed between the first encapsulation layer and the display function layer 24, or serves as the first inorganic encapsulation layer.

Specifically, in an embodiment of the present disclosure, as shown in FIG. 24, in some embodiments, the display panel may further include a first encapsulation layer 71 located on a side, away from the substrate 100, of the display function layer 24. The first encapsulation layer 71 includes a plurality of first encapsulation portions 711 respectively disposed in the plurality of isolation openings 301.

The first encapsulation layer 71 is configured to provide encapsulation protection for the light-emitting unit 220. The first encapsulation layer 71 includes a plurality of first encapsulation portions 711, which correspond to the plurality of isolation openings 301. That is, the plurality of first encapsulation portions 711 correspond to the plurality of light-emitting units 220. In this design, the plurality of first encapsulation portions 711 of the first encapsulation layer 71 may independently encapsulate the plurality of light-emitting units 220, thereby improving encapsulation reliability.

Meanwhile, the material of the first encapsulation layer 71 will not continuously exist between adjacent isolation units 31, so the first encapsulation layer 71 will not have a significant impact on the stretching performance of the display panel. The first encapsulation portions 711 are provided corresponding to the light-emitting units 220, so that the first encapsulation portions 711 may move with the light-emitting units 220 and the isolation units 31 to meet the stretching requirement of the display panel.

Material of the first encapsulation layer 71 is not limited in the present disclosure. For example, the first encapsulation layer 71 may include inorganic material.

Similarly, in some embodiments, as shown in FIG. 24, the display panel may further include a second encapsulation layer 72 disposed on a side, away from the substrate 100, of the first encapsulation layer 71. The second encapsulation layer 72 includes a plurality of second encapsulation portions 721 separately disposed in the plurality of isolation openings 301.

Both the first encapsulation layer 71 and the second encapsulation layer 72 are used for encapsulation. The structure of the second encapsulation layer 72 is similar to the structure of the first encapsulation layer 71. The second encapsulation layer 72 also includes a plurality of second encapsulation portions 721 corresponding to the plurality of light-emitting units 220. Therefore, the second encapsulation portion 721 may move with the isolation openings 301 and the isolation unit 31 to meet the stretching requirement of the display panel. Material of the second encapsulation layer 72 is not limited in the present disclosure. For example, the second encapsulation layer 72 may include organic material. It should be noted that the second encapsulation portion 721 may also be filled into the first light-transmitting opening 302, and the materials of the second encapsulation portion 721 and the first transparent filling portion T may be the same or different.

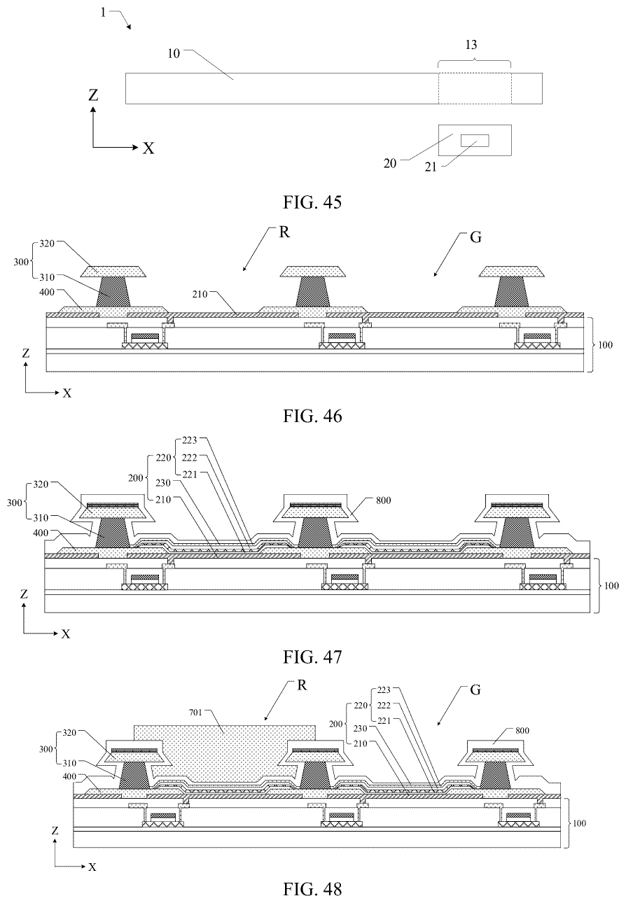

At least one embodiment of the present disclosure provides a display device, as shown in FIG. 45. The display device 1 includes a recognition device 20 and the display panel 10 provided by any of the above embodiments, where at least part of an orthographic projection of the recognition device 20 on the substrate 100 overlaps with the first region 13.

For example, in some embodiments of the present disclosure, the recognition device 20 may include at least one fingerprint recognition sensor 21. For example, the fingerprint recognition sensor 21 may be disposed on a side, away from the display function layer 24, of the substrate 100. In one embodiment, the fingerprint recognition sensor 21 may also be disposed within the substrate 100.

For example, in other embodiments of the present disclosure, the recognition device 20 may be a camera located on a side, away from the display function layer 24, of the substrate 100. In one embodiment, the camera may also be disposed within the substrate 100.

For example, in the embodiment of the present disclosure, the display device may be any product or component with display function, such as a television, a digital camera, a mobile phone, a watch, a tablet, a laptop, a navigation device, and so on.

In some embodiments of the present disclosure, as shown in FIG. 55, the pixel defining layer 400 has a first thickness H1 where an orthographic projection of the pixel defining layer 400 overlaps with an orthographic projection of the first light-transmitting opening 302, and a second thickness H2 where the orthographic projection of the pixel defining layer 400 overlaps with an orthographic projection of the isolation structure 300. The first thickness H1 is less than the second thickness H2.

Therein, the first thickness H1 refers to a thickness of at least one position of the pixel defining layer 400, where the orthographic projection of the pixel defining layer 400 on the substrate overlaps with the orthographic projection of the first light-transmitting opening 302 on the substrate. The second thickness H2 refers to a thickness of at least one position of the pixel defining layer 400, where the orthographic projection of the pixel defining layer 400 on the substrate overlaps with the orthographic projection of the isolation structure 300 on the substrate. In one embodiment, the second thickness H2 refers to a thickness of at least one position of the pixel defining layer 400 located below the first isolation layer 310 of the isolation structure 300.

In this embodiment of the present disclosure, the thickness of the pixel defining layer 400 at the first light-transmitting opening 302 is smaller than the thickness of the pixel defining layer 400 below the isolation structure 300, making the pixel defining layer 400 at the first light-transmitting opening 302 thinner, thereby improving transmittance of film layers at the first light-transmitting opening 302. Meanwhile, by retaining the pixel defining layer 400 at the first light-transmitting opening 302, water vapor may be blocked from entering the display region through the pixel defining layer 400 at the first light-transmitting opening 302.

In some embodiments of the present disclosure, as shown in FIG. 55, a side, facing away from the substrate 100, of the pixel defining layer 400, where the orthographic projection of the pixel defining layer 400 on the substrate overlaps with the orthographic projection of the first light-transmitting opening 302 on the substrate, is provided with at least one groove 801.

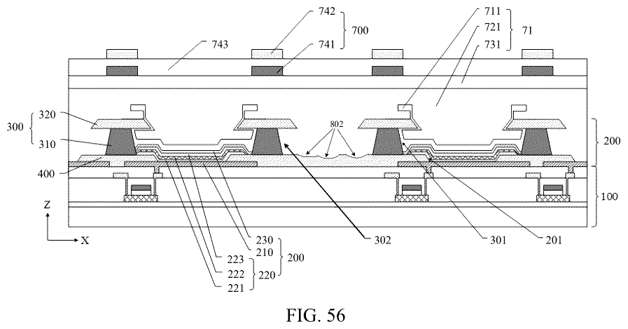

In some embodiments of the present disclosure, as shown in FIG. 56, a side, facing away from the substrate 100, of the pixel defining layer 400, where the orthographic projection of the pixel defining layer 400 on the substrate overlaps with the orthographic projection of the first light-transmitting opening 302 on the substrate, is provided with at least one recess 802.

In this this embodiment of the present disclosure, the groove 801 or the recess 802 is provided in the pixel defining layer 400 at a position corresponding to the first light-transmitting opening 302, to reduce the thickness of the pixel defining layer 400 at the position corresponding to the first light-transmitting opening 302 and improve the transmittance of the film layers at the first light-transmitting opening 302.

The above description is merely one embodiment of this specification and is not intended to limit it. Any modifications, equivalent substitutions, and so on, made within the spirit and principles of this specification shall be included within the protection scope of this specification.

At least one embodiment of the present disclosure provides a preparation method for a display panel. The preparation process of the display panel 10 shown in FIG. 43 will be described in the following. As shown in FIG. 44, the preparation method of a display panel provided in the present disclosure includes the following steps.
Step S10: preparing a substrate. After preparing the substrate 100, the method may further include: forming a plurality of first electrodes 210 arranged in an array on the substrate 100; depositing an insulating material film layer (such as an inorganic material film layer) on the substrate 100 with the first electrode 210. In one embodiment, the insulating material film layer may be performed a patterning process to form a pixel defining layer 400 (with a grid like planar shape), which covers a gap between adjacent first electrodes 210. Thus, the planar shape of the pixel defining layer 400 is in a grid shape.
Step S20: preparing an isolation structure on the substrate, where the isolation structure is configured to define a plurality of isolation openings. For example, a first isolation layer 310 and a second isolation layer 320 are formed on the display panel, and the plurality of isolation openings are formed in the first isolation layer 310 and the second isolation layer 320.
Step S30: preparing a display function layer on the substrate, where the display function layer includes a light-emitting device located in the isolation opening. And step S40: preparing a first light-transmitting opening in the isolation structure.

At least one embodiment of the present disclosure further provides a preparation method for a display panel. The preparation process of the display panel 10 shown in FIG. 43 will be described with reference to FIGS. 46 to 49 below.

As shown in FIG. 46, a substrate 100 is prepared and first electrodes 210 arranged in an array are formed on the substrate 100. An insulating material film layer (such as an inorganic material film layer) is deposited on the substrate 100 with the first electrode 210. A first isolation layer 310 and a second isolation layer 320 are formed on the display panel, where an isolation opening and an first light-transmitting opening (not shown in this figure, please refer to the previous figures) are formed. The insulating material film layer is performed a patterning process to form a pixel defining layer 400 (with a grid like planar shape), which covers a gap between adjacent first electrodes 210. Thus, the planar shape of the pixel defining layer 400 is grid like.

In the embodiment of the present disclosure, the patterning process may be a photolithography patterning process. For example, the patterning process may include: coating photoresist on a structural layer to be patterned; exposing the photoresist with a mask;
developing the exposed photoresist to obtain a photoresist pattern; etching the structural layer with the photoresist pattern (both dry and wet etching are available); and may remove the photoresist pattern. In a case where the material of the structural layer (such as the photoresist pattern 701 below) includes the photoresist, the structural layer may be directly exposed through a mask to form a desired pattern.

As shown in FIG. 47, a light-emitting unit 220 and a second electrode 230 are evaporated on the substrate 100 to form the light-emitting device 200 in each isolation opening of the isolation structure 300. In the evaporation process, the mask is not used, so the evaporation material will also be deposited on the second isolation layer 320 and in the first light-transmitting opening 302. A protection layer 800 is deposited to cover the light-emitting device 200. In this stage, the protection layer 800 will cover the entire second region during this stage. For example, a light-emitting layer 222 of a light-emitting unit 220 evaporated may be configured to emit red light (R), that is, at this stage, a light-emitting device 200 emitting red light (the first light-emitting device mentioned above) may be formed in each isolation opening of the isolation structure 300.

As shown in FIG. 48, a photoresist is formed (e.g. coating, etc.) on the substrate 100 with the protection layer 800, and a patterning process is performed on the photoresist to form a photoresist pattern 701. The photoresist pattern 701 only covers part of the isolation openings (corresponding to the first light-emitting device after the display panel is prepared) of the isolation structure 300.

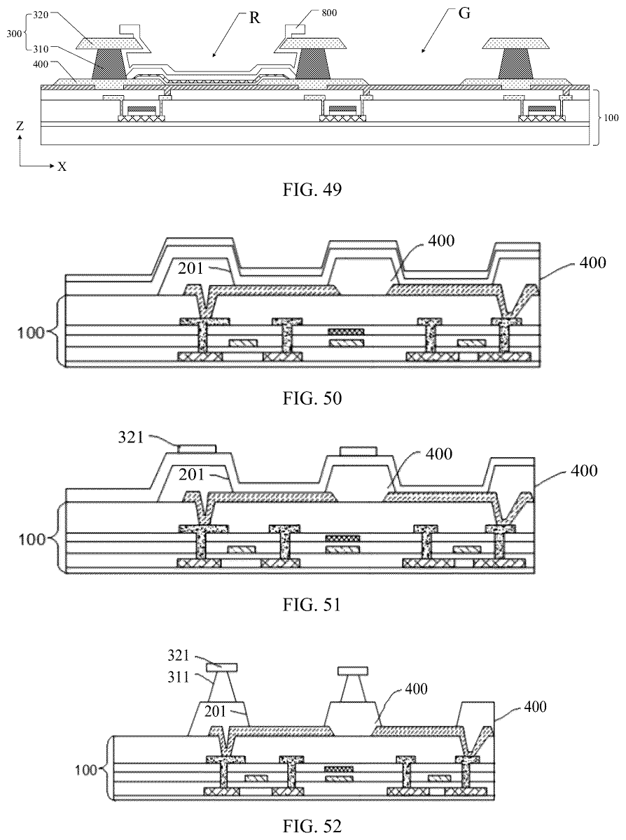

As shown in FIG. 49, the surface of the display panel is etched using the photoresist pattern 701 as a mask to remove the protection layer 800, the second electrode 230, and the light-emitting unit 220 not covered by the photoresist pattern 701; and then the residual photoresist pattern 701 are removed.

Steps from FIGS. 46 to 49 are repeated to form light-emitting devices 200 emitting green light and blue light in other isolation openings separately, and a display panel is formed as shown in FIG. 34.

The embodiment of the present disclosure also provides a preparation method for a display panel 10. The preparation process of the display panel 10 shown in FIG. 27 will be described with reference to FIGS. 50 to 53 below.
Step S01: preparing a first transparent material layer and a second transparent material layer on a substrate, where the second transparent material layer is located on a side, away from the substrate, of the first transparent material layer.
Step S02: performing pattern process on the first transparent material layer and the second transparent material layer to form a first transparent layer and a second transparent layer, where an orthographic projection of the first transparent layer on the substrate is located within an orthographic projection of the second transparent layer on the substrate, and the first transparent layer and the second transparent layer are stacked to form an isolation structure.
Step S03: preparing a light-emitting layer, where the light-emitting layer includes a plurality of light-emitting units spaced apart from each other and each of the plurality of light-emitting units is located in a corresponding isolation opening.

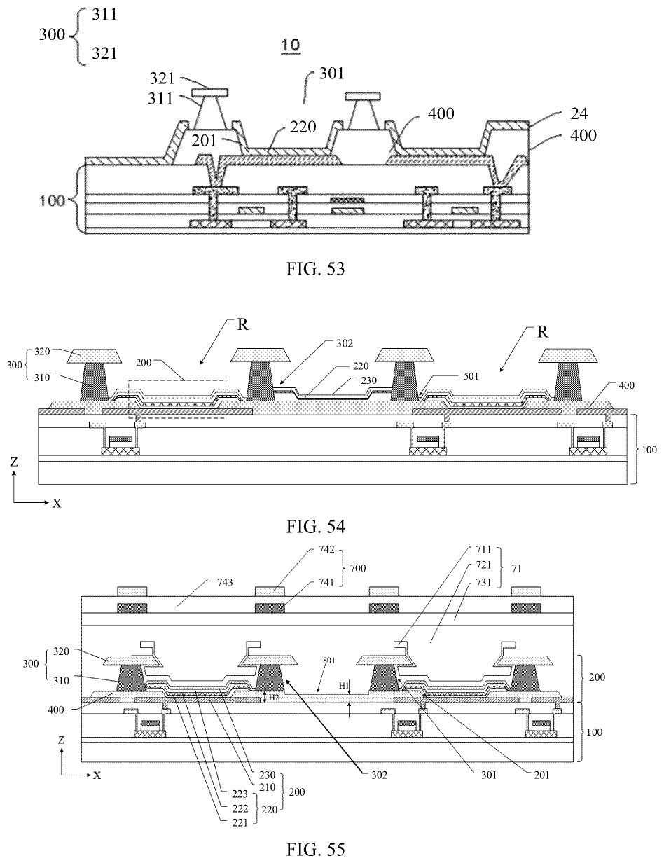

According to the preparation method in the embodiment of the present disclosure, as shown in FIG. 50, the first transparent material layer and the second transparent material layer are provided through step S01. As shown in FIG. 51 and FIG. 52, the first transparent layer 311 and the second transparent layer 321 are prepared through step S02. As shown in FIG. 53, the display function layer 24 is finally prepared through step S03, and the light-emitting unit 220 is located in the isolation opening 301 to achieve light-emitting display. The isolation structure 300 includes the first transparent layer 311 and the second transparent layer 321. The orthographic projection of the first transparent layer 311 on the substrate 100 is located within the orthographic projection of the second transparent layer 321 on the substrate 100, so that sidewall of the first transparent layer 311 is concave relative to sidewall of the second transparent layer 321, thereby separating the display function layer 24 and forming light-emitting units 220 mutually disconnected. Therefore, crosstalk of carriers in the display function layer 24 may be reduced, further reducing development and use of fine masks and reducing the preparation cost. As the first transparent layer 311 and the second transparent layer 321 both have a high light transmittance rate, when the display panel 10 is provided with a photosensitive component, photosensitive effect of the photosensitive component may be improved by the isolation structure 300.

In some embodiments, the step “performing patterning process on the first transparent material layer and the second transparent material layer to form a first transparent layer 311 and a second transparent layer 321”, may further include:
performing dry etching to the first transparent material layer to form the first transparent layer;
performing wet etching to the second transparent material layer to form the second transparent layer.

In these embodiments, the second transparent layer 321 and the first transparent layer 311 are etched by different etching methods, so that the etching of the first transparent layer 311 and the second transparent layer 321 do not affect each other, so that the sidewall of the first transparent layer 311 is concave relative to the sidewall of the second transparent layer 321, thereby achieving the isolation effect on the display function layer 24 and the second electrode layer 2300.

In some embodiments, a third transparent material layer may provide on the substrate 100, and the third transparent material layer is located between the first transparent material layer and the substrate 100. After the step of performing dry etching to the first transparent material layer to form the first transparent layer 311, the method further includes:
performing wet etching to the third transparent material layer to form the third transparent layer;

By performing dry etching to the first transparent material layer, an orthographic projection of the first transparent layer on the substrate is located within an orthographic projection of the third transparent layer on the substrate.

In these embodiments, a third transparent material layer is provided between the first transparent material layer and the substrate 100. When the first transparent material layer is etched, the third light-transmitting material layer may provide a certain protection effect on the substrate 100, reducing the entry of etching waste from the first transparent material layer into the substrate 100 and solving a problem that substrate 100 is easily eroded by the etching waste. The orthographic projection of the first transparent layer 311 on the substrate 100 is located within an orthographic projection of the third transparent layer 331 on the substrate 100, that is, the bottom surface, closer to the substrate 100, of the first transparent layer 311 is totally located above the third transparent layer 331. When preparing the second electrode 230, the edge of the third transparent layer protrudes from the first transparent layer 311, which increases a contact area between the third transparent layer and the second electrode 230, thereby improving the connection performance between the second electrode 230 and the third transparent layer.

In some embodiments, before the step of preparing a display function layer 24 on the substrate 100, the method further includes:
depositing a transparent metal material layer on a side, away from the substrate, of the isolation structure, and performing wet etching to the transparent metal material to form an connection portion. The connection portion is connected to a sidewall, facing the isolation opening, of the isolation structure.

In these embodiments, the connection portion 250 is provided on the sidewall, facing the isolation opening 301, of the isolation structure 300, so that the third transparent layer 331 and the second electrode 230 is electrically connected through the connection portion 250 to improve the connection performance between the second electrode 230 and the third transparent layer 331.

Of course, when the transparent metal material is performed wet etching to form the connection portion 250, the transparent metal material layer deposited on the side, away from the substrate 100, of the isolation structure 300 may be retained without affecting the light-transmitting performance.

According to the embodiments of the present disclosure as described above, these embodiments do not exhaustively describe all the details, nor do they limit the disclosure to the specific embodiments described. Obviously, many modifications and variations can be made based on the above description. These embodiments are selected and specifically described in this specification to better explain the principles and practical applications of the present disclosure, and good use of the present disclosure and its modifications can be made. The present disclosure is only limited by the scope of the claims and all equivalents thereof.

In some embodiments of the present disclosure, some film layers in the light-emitting unit, such as the light-emitting layer, may be prepared by non-evaporation methods such as inkjet printing, and the specific selection can be based on the material of these film layers. For example, where these film layers are high resolution materials and are not suitable for evaporation, inkjet printing can be used for preparation.

What is claimed is:

1. A display panel, comprising:
a substrate;
a pixel defining layer, located on the substrate and comprising a plurality of fourth openings;
an isolation structure layer, provided on the pixel defining layer, wherein the isolation structure layer comprises a light-transmitting portion and a plurality of isolation openings, and an orthographic projection of an isolation opening on the substrate at least partially overlaps with an orthographic projection of a fourth opening on the substrate; and
a display function layer, comprising a light-emitting device provided corresponding to the isolation opening;
wherein an orthographic projection of the light-transmitting portion on the substrate overlaps with an orthographic projection of the pixel defining layer on the substrate.

2. The display panel according to claim 1, wherein the light-transmitting portion comprises a first light-transmitting opening, the isolation structure layer comprises an isolation structure to define the plurality of isolation openings, and the first light-transmitting opening is provided in the isolation structure.

3. The display panel according to claim 2, wherein the first light-transmitting opening extends through the isolation structure in a light emitting direction of the light-emitting device, and the first light-transmitting opening is spaced apart from the isolation opening.

4. The display panel according to claim 2, further comprising a second electrode layer located on a side, away from the substrate, of the display function layer, wherein the second electrode layer comprises a plurality of second electrodes spaced apart from each other and located in the plurality of isolation openings respectively, and
the isolation structure comprises a first isolation layer and a second isolation layer stacked in layers, the first isolation layer is located between the substrate and the second isolation layer, an orthographic projection of the first isolation layer on the substrate is located within an orthographic projection of the second isolation layer on the substrate, and the first isolation layer is electrically connected to the plurality of second electrodes.

5. The display panel according to claim 4, wherein an orthographic projection of a side, facing away from the substrate, of the first isolation layer on the substrate is located within an orthographic projection of a side, facing the substrate, of the first isolation layer on the substrate.

6. The display panel according to claim 4, wherein the isolation structure further comprises a third isolation layer, the third isolation layer is disposed on a side, close to the substrate, of the first isolation layer, and the orthographic projection of the first isolation layer on the substrate is located within an orthographic projection of the third isolation layer on the substrate.

7. The display panel according to claim 2, wherein an orthographic projection of the first light-transmitting opening on the substrate overlaps with the orthographic projection of the pixel defining layer on the substrate.

8. The display panel according to claim 7, wherein the orthographic projection of the first light-transmitting opening on the substrate is located within the orthographic projection of the pixel defining layer on the substrate.

9. The display panel according to claim 7, wherein the pixel defining layer has a first thickness where the orthographic projection of the pixel defining layer on the substrate overlaps with the orthographic projection of the first light-transmitting opening on the substrate, and a second thickness where the orthographic projection of the pixel defining layer overlaps with an orthographic projection of the isolation structure on the substrate, and the first thickness is less than the second thickness.

10. The display panel according to claim 7, wherein a side, facing away from the substrate, of the pixel defining layer, where the orthographic projection of the pixel defining layer on the substrate overlaps with the orthographic projection of the first light-transmitting opening on the substrate, is provided with a groove or a recess.

11. The display panel according to claim 2, further comprising: a first transparent filling portion filled in the first light-transmitting opening.

12. The display panel according to claim 2, wherein the substrate comprises:
a base; and
an array layer located on a side, close to the display function layer, of the substrate, the array layer comprises a first wiring, and an orthographic projection of the first wiring on the substrate does not overlap or partially overlaps with an orthographic projection of the first light-transmitting opening on the substrate.

13. The display panel according to claim 1, further comprising: an encapsulation layer located on a side, away from the substrate, of the isolation structure layer and the display function layer, wherein the encapsulation layer comprises a first encapsulation layer, a second encapsulation layer, and a third encapsulation layer sequentially stacked in layers in a direction facing away from the substrate; and
the light-transmitting portion comprises a first light-transmitting opening, the isolation structure layer comprises an isolation structure, and the first light-transmitting opening is disposed in the isolation structure; and part of the second encapsulation layer is located within the first light-transmitting opening.

14. The display panel according to claim 13, wherein the second encapsulation layer is in contact with the pixel defining layer in the first light-transmitting opening and a side wall of the isolation structure, respectively.

15. The display panel according to claim 13, wherein an orthographic projection of the first encapsulation layer on the substrate does not overlap with an orthographic projection of the first light-transmitting opening on the substrate.

16. The display panel according to claim 13, wherein the first encapsulation layer located on a side, facing away from the substrate, of the isolation structure layer is spaced apart from the isolation structure layer by a gap.

17. The display panel according to claim 1, further comprising a touch structure, located on a side, facing away from the substrate, of the isolation structure layer; wherein
the touch structure comprises a plurality of touch electrodes, the touch electrodes define at least one touch opening, and an orthographic projection of the touch opening on the substrate at least partially overlaps with the orthographic projection of the light-transmitting portion on the substrate.

18. The display panel according to claim 1, further comprising a first electrode layer, wherein the first electrode layer comprises a plurality of first electrodes, the fourth opening is configured to expose a first electrode, and an orthographic projection of the first electrode layer on the substrate does not overlap with the orthographic projection of the light-transmitting portion on the substrate.

19. The display panel according to claim 18, wherein an orthographic projection of the first electrode on the substrate overlaps with an orthographic projection of the isolation structure layer on the substrate.

20. The display panel according to claim 2, further comprising: a transparent conductive layer located on a side, facing away from the substrate, of the pixel defining layer and an orthographic projection of the first light-transmitting opening is located within an orthographic projection of the transparent conductive layer on the substrate.
